(19) United States
(12) Patent Application Publication
(10) Pub. No.: US 2015/0168503 A1
(43) Pub. Date: Jun. 18, 2015

(54) MAGNETIC FIELD SENSOR AND SENSING APPARATUS USING THE SAME

(71) Applicant: SAMSUNG ELECTRO-MECHANICS CO., LTD., Suwon-Si (KR)

(72) Inventors: Dae Ho Kim, Suwon-Si (KR); Eun Tae Park, Suwon-Si (KR)

(73) Assignee: SAMSUNG ELECTRO-MECHANICS CO., LTD., Suwon-Si (KR)

(21) Appl. No.: 14/304,870

(22) Filed: Jun. 13, 2014

(30) Foreign Application Priority Data
Dec. 18, 2013 (KR) 10-2013-0158466

(51) Int. Cl. G01R 33/02

(52) U.S. Cl. CPC G01R 33/02

(57) ABSTRACT

Disclosed herein are a magnetic field sensor and a sensing apparatus using the same. The present invention provides a magnetic field sensor including: a magnetic field detection unit which includes a substrate, a piezoelectric driving body formed on the substrate, and a magnetostrictive layer stacked on one portion of the piezoelectric driving body and is vibrated at a vibration frequency changed from a natural frequency in proportion to a magnitude of an external magnetic field; and a control unit which drives the piezoelectric driving body with a constant AC voltage and calculates a magnitude of the external magnetic field from an output voltage output from the magnetic field detection unit, and a sensing apparatus using the same.

### CROSS REFERENCE TO RELATED APPLICATION

This application claims the benefit of Korean Patent Application No. 10-2013-0158466, filed on Dec. 18, 2013, entitled “Magnetic Field Sensor and Sensing Apparatus Using Thereof” which is hereby incorporated by reference in its entirety into this application.

### BACKGROUND OF THE INVENTION

1. Technical Field

The present invention relates to a magnetic field sensor and a sensing apparatus using the same.

2. Description of the Related Art

A magnetic field sensor is configured of a multi-layer composite structure of a piezoelectric layer and a magnetostrictive layer and uses a principle which transfers a change in a structure of the magnetostrictive layer due to an external magnetic field to generate an electrical signal.

According to the prior art, the magnetic field sensor as described above has a simple parallel plate capacitor which has the piezoelectric layer and the magnetostrictive layers attached to both sides of the piezoelectric layer.

In the structure as described above, most of the magnetostrictive layers have conducting characteristics and therefore also serves as an electrode of the parallel plate capacitor.

In the structure as described above, when not being applied with the external magnetic field, the magnetic field sensor keeps an original size and a potential between upper and lower electrodes thereof is the same.

Unlike, when the external magnetic field is generated, a length of the magnetostrictive layer is contracted and therefore the mechanically connected piezoelectric layer is also contracted and a potential difference occurs between the upper and lower electrodes.

A magnitude of the occurring potential difference is proportional to a magnitude of the external magnetic field and a magnitude of the external magnetic field may be calculated by electrically measuring the potential difference.

As a result, the magnetic field sensor may be used to measure, in particular, an external AC magnetic field. When the magnitude of the external magnetic field is changed to an AC form, the magnetostrictive layer is repeatedly contracted and expanded and the piezoelectric layer undergoes the same contraction and expansion, thereby generating an electrical signal having the same frequency. The magnitude of the AC potential difference is proportional to the external AC magnetic field.

Meanwhile, in the structure of the parallel plate capacitor, since the magnitude of the potential difference is not constantly kept when the magnetic field is kept at a predetermined magnitude and the change magnitude of the magnetic field is very slowly generated, it is difficult to measure the magnetic field.

To solve the above problem, according to the prior art, the magnitude of the external magnetic field is measured by measuring the AC voltage generated from the piezoelectric layer while additionally applying the AC magnetic field to all the magnetic field sensors in addition to a DC external magnetic field when the change in the external magnetic field is very slow or the magnitude of the magnetic field is constant.

To this end, for example, the magnetic field is generated in all the magnetic field sensors by using, for example, an AC magnetic field generating coil to generate the vibration, thereby measuring the external DC magnetic field.

As another example, the electric field is applied to the piezoelectric layer to induce the vibration and then the change in a vibration frequency due to the external magnetic field is measured.

The method applies the electric field to the piezoelectric layer to induce the vibration and then measures the change in the vibration frequency due to the external magnetic field.

In this case, to apply the electric field, an electrode having a horizontal cross structure formed on one surface of the piezoelectric layer is used. Therefore, the vibration is vibrated in a high overtone type, not a basic vibration, such that the vibration frequency is increased. When being applied with the electric field having a constant size from the outside, the structure of the magnetostrictive layer is changed, such that the vibration frequency of the piezoelectric layer is changed.

In this case, the change amount of the vibration frequency is proportional to the magnitude of the external magnetic field. That is, when the change in the vibration frequency is measured, the magnitude of the external magnetic field may be calculated.

The prior art has a disadvantage in that it is difficult to form the electrode having a complicated shape on a lower surface of the piezoelectric layer and excessively increase the vibration frequency depending on the overtone characteristics of the vibration due to the electrode form.

### PRIOR ART DOCUMENT

### Patent Document

(Patent Document 1) U.S. Pat. No. 6,580,271

(Patent Document 2) U.S. Pat. No. 7,965,020

### SUMMARY OF THE INVENTION

The present invention has been made in an effort to provide a magnetic field sensor and a sensing apparatus using the same capable of calculating a magnitude of an external magnetic field by stacking a magnetostrictive layer on one portion of a piezoelectric layer, vibrating the piezoelectric layer using driving electrodes disposed at both sides of the piezoelectric layer, and using a change in a vibration frequency of an output voltage of the piezoelectric layer.

According to a preferred embodiment of the present invention, there is provided a magnetic field sensor, including: a magnetic field detection unit which includes a substrate, a piezoelectric driving body formed on the substrate, and a magnetostrictive layer stacked on one portion of the piezoelectric driving body and is vibrated at a vibration frequency changed from a natural frequency in proportion to a magnitude of an external magnetic field; and a control unit which drives the piezoelectric driving body with a constant AC voltage and calculates a magnitude of the external magnetic field from an output voltage output from the magnetic field detection unit, wherein the piezoelectric driving body has an end fixed to the substrate and the other end protruding on a side of the substrate in the state in which the other end is not supported to the substrate and has a rectangular bar shape.

The piezoelectric driving body may include: a first electrode which has an end fixed to the substrate and the other end protruding on a side of the substrate in the state in which the other end is not supported to the substrate and has a rectangular bar shape; a piezoelectric layer which is stacked on the first electrode; and a second electrode which is stacked on the piezoelectric layer.

The magnetic field sensor may further include: a sensing electrode which is formed to be separated from a second electrode formed on the piezoelectric layer of the piezoelectric driving body, wherein the control unit includes a driver which applies the constant AC voltage to the first electrode and the second electrode to vibrate the piezoelectric layer; and a sensor which measures a voltage across the piezoelectric layer using the first electrode and the sensing electrode to measure the vibration frequency based on a change amount of the voltage and calculates the change amount from the natural frequency of the measured vibration frequency to measure the magnitude of the external magnetic field.

The magnetic field sensor may further include: a reference unit which includes a reference piezoelectric driving body formed to have the same structure as the piezoelectric driving body of the magnetic detection unit and made of the same material as the piezoelectric driving body of the magnetic detection unit and is vibrated at the natural frequency.

According to another preferred embodiment of the present invention, there is provided a magnetic field sensor, including: a magnetic field detection unit which includes a substrate, a piezoelectric driving body formed on the substrate, and a magnetostrictive layer stacked on one portion of the piezoelectric driving body and is vibrated at a vibration frequency changed from a natural frequency in proportion to a magnitude of an external magnetic field; and a control unit which drives the piezoelectric driving body with a constant AC voltage and calculates a magnitude of the external magnetic field from an output voltage output from the magnetic field detection unit, wherein the substrate is provided with a groove, and the piezoelectric driving body includes: a first electrode which has ends fixed to both sides of the groove and has a rectangular bar shape crossing the groove; a piezoelectric layer which is stacked on the first electrode; and a second electrode which is stacked on the piezoelectric layer.

The magnetic field sensor may further include: a sensing electrode which is formed to be separated from a second electrode formed on the piezoelectric layer of the piezoelectric driving body, wherein the control unit includes a driver which applies the constant AC voltage to the first electrode and the second electrode to vibrate the piezoelectric layer; and a sensor which measures a voltage across the piezoelectric layer using the first electrode and the sensing electrode to measure the vibration frequency based on a change amount of the voltage and calculates the change amount from the natural frequency of the measured vibration frequency to measure the magnitude of the external magnetic field.

The magnetic field sensor may further include: a reference unit which includes a reference piezoelectric driving body formed to have the same structure as the piezoelectric driving body of the magnetic detection unit and made of the same material as the piezoelectric driving body of the magnetic detection unit and is vibrated at the natural frequency.

According to still another preferred embodiment of the present invention, there is provided a sensing apparatus, including: a first magnetic field detection unit which includes a substrate, a first piezoelectric driving body formed on the substrate, and a first magnetostrictive layer stacked on one portion of the first piezoelectric driving body and is vibrated at a vibration frequency changed from a natural frequency in proportion to a magnitude of an external magnetic field in a first direction; a second magnetic field detection unit which includes a second piezoelectric driving body formed on the substrate differently from a direction of the first piezoelectric driving body and a second magnetostrictive layer stacked on one portion of the second piezoelectric driving body and is vibrated at the vibration frequency changed from the natural frequency in proportion to a magnitude of an external magnetic field in a second direction; and a control unit which drives the first piezoelectric driving body and the second piezoelectric driving body with a constant AC voltage and calculates the magnitudes of the external magnetic fields in the first direction and the second direction from an output voltage output from the first magnetic field detection unit and the second magnetic field detection unit, the first piezoelectric driving body has an end fixed to the substrate and the other end protruding on a side of the substrate in the state in which the other end is not supported to the substrate and has a rectangular bar shape, wherein the second piezoelectric driving body has an end fixed to the substrate and the other end protruding on a side of the substrate in the state in which the other end is not supported to the substrate and has a rectangular bar shape.

The first piezoelectric driving body may include: a first electrode which has an end fixed to the substrate and the other end protruding on a side of the substrate in the state in which the other end is not supported to the substrate and has a rectangular bar shape; a first piezoelectric layer which is stacked on the first electrode; and a second electrode which is stacked on the first piezoelectric layer, wherein the second piezoelectric driving body includes: a third electrode which has an end fixed to the substrate and the other end protruding on a side of the substrate in the state in which the other end is not supported to the substrate and has a rectangular bar shape; a second piezoelectric layer which is stacked on the third electrode; and a fourth electrode which is stacked on the second piezoelectric layer.

The first piezoelectric driving body may include a first sensing electrode which is formed to be separated from the first electrode formed on the first piezoelectric layer, and the second piezoelectric driving body may include a second sensing electrode which is formed to be separated from a fourth electrode formed on the second piezoelectric layer, and the control unit may include: a first driver which applies a constant AC voltage to the first electrode and the second electrode to vibrate the first piezoelectric layer; a second driver which applies a constant AC voltage to the third electrode and the fourth electrode to vibrate the second piezoelectric layer; a first sensor which measures a voltage across the first piezoelectric layer using the first electrode and the first sensing electrode to measure a first vibration frequency from a change amount of the voltage, and calculates the change amount from a first natural frequency of the measured first vibration frequency to measure the magnitude of the external magnetic field in the first direction; and a second sensor which measures a voltage across the second piezoelectric layer using the third electrode and the second sensing electrode to measure a second vibration frequency from a change amount of the voltage, and calculates the change amount from a second natural frequency of the measured second vibration frequency to measure the magnitude of the external magnetic field.

The first magnetic field detection unit may include a first reference unit which includes a first reference unit which includes a first reference piezoelectric driving body formed to have the same structure as the first piezoelectric driving body and made of the same material as the first piezoelectric driving body and is vibrated at a first natural frequency; and the second magnetic field detection unit may include a second reference unit which includes a second reference unit which includes a second reference piezoelectric driving body formed to have the same structure as the second piezoelectric driving body and made of the same material as the second piezoelectric driving body and is vibrated at a second natural frequency.

According to still another preferred embodiment of the present invention, there is provided a sensing apparatus, including: a first magnetic field detection unit which includes a substrate, a first piezoelectric driving body formed on the substrate, and a first magnetostrictive layer stacked on one portion of the first piezoelectric driving body and is vibrated at a vibration frequency changed from a natural frequency in proportion to a magnitude of an external magnetic field in a first direction; a second magnetic field detection unit which includes a second piezoelectric driving body formed on the substrate differently from a direction of the first piezoelectric driving body and a second magnetostrictive layer stacked on one portion of the second piezoelectric driving body and is vibrated at the vibration frequency changed from the natural frequency in proportion to a magnitude of an external magnetic field in a second direction; and a control unit which drives the first piezoelectric driving body and the second piezoelectric driving body with a constant AC voltage and calculates the magnitudes of the external magnetic fields in the first direction and the second direction from an output voltage output from the first magnetic field detection unit and the second magnetic field detection unit, wherein the substrate is provided with a groove, the first piezoelectric driving body includes: a first electrode which has ends fixed to both sides of the groove and has a rectangular bar shape crossing the groove; a first piezoelectric layer which is stacked on the first electrode; and a second electrode which is stacked on the first piezoelectric layer, and the second piezoelectric driving body includes: a third electrode which has ends fixed to both sides of the groove and has a rectangular bar shape crossing the groove; a second piezoelectric layer which is stacked on the third electrode; and a fourth electrode which is stacked on the second piezoelectric layer.

The sensing apparatus may further include: a first sensing electrode which is formed to be separated from the first electrode formed on the piezoelectric layer of the first piezoelectric driving body, and a second sensing electrode which is formed to be separated from the fourth electrode formed on the piezoelectric layer of the second piezoelectric driving body, wherein the control unit includes: a first driver which applies a constant AC voltage to the first electrode and the second electrode to vibrate the first piezoelectric layer; a second driver which applies a constant AC voltage to the third electrode and the fourth electrode to vibrate the second piezoelectric layer; a first sensor which measures a voltage across the first piezoelectric layer using the first electrode and the first sensing electrode to measure a first vibration frequency from a change amount of the voltage, and calculates the change amount from a first natural frequency of the measured first vibration frequency to measure the magnitude of the external magnetic field in the first direction; and a second sensor which measures a voltage across the second piezoelectric layer using the third electrode and the second sensing electrode to measure a second vibration frequency from a change amount of the voltage, and calculates the change amount from a second natural frequency of the measured second vibration frequency to measure the magnitude of the external magnetic field.

The first magnetic field detection unit may include a first reference unit which includes a first reference piezoelectric driving body formed to have the same structure as the first piezoelectric driving body and made of the same material as the first piezoelectric driving body and is vibrated at a first natural frequency; and the second magnetic field detection unit may include a first reference unit which includes a second reference piezoelectric driving body formed to have the same structure as the second piezoelectric driving body and made of the same material as the second piezoelectric driving body and is vibrated at a second natural frequency.

According to yet another preferred embodiment of the present invention, there is provided a sensing apparatus, including: a first magnetic field detection unit which includes a substrate, a first piezoelectric driving body formed on the substrate, and a first magnetostrictive layer stacked on one portion of the first piezoelectric driving body and is vibrated at a first vibration frequency changed from a first natural frequency in proportion to a magnitude of an external magnetic field in a first direction vertical to the first magnetostrictive layer; a flux concentrator which is mounted in parallel with the external magnetic field in the first direction to induce the external magnetic field in the first direction to a first magnetostrictive layer of the first magnetic field detection unit; and a control unit which drives the first piezoelectric driving body with a constant AC voltage and calculates a magnitude of the external magnetic field in the first direction from an output voltage output from the first magnetic field detection unit.

The first piezoelectric driving body may have an end fixed to the substrate and the other end protruding on a side of the substrate in the state in which the other end is not supported to the substrate and has a rectangular bar shape.

The first piezoelectric driving body may include: a first electrode which has an end fixed to the substrate and the other end protruding on a side of the substrate in the state in which the other end is not supported to the substrate and has a rectangular bar shape; a first piezoelectric layer which is stacked on the first electrode; and a second electrode which is stacked on the first piezoelectric layer.

The sensing apparatus may further include: a first sensing electrode which is formed to be separated from the second electrode formed on the first piezoelectric layer of the first piezoelectric driving body, wherein the control unit includes a first driver which applies a constant AC voltage to the first electrode and the second electrode to vibrate the first piezoelectric layer; and a first sensor which measures a voltage across the first piezoelectric layer using the first electrode and the first sensing electrode to measure a vibration frequency from a change amount of the voltage and calculates the change amount from the natural frequency of the measured vibration frequency to measure the magnitude of the external magnetic field.

The sensing apparatus may further include: a first reference magnetic field detection unit which includes a first reference piezoelectric driving body formed to have the same structure as the first piezoelectric driving body of the first magnetic field detection unit and made of the same material as the first piezoelectric driving body of the first magnetic field detection unit and is vibrated at the first natural frequency.

The substrate may be provided with a first groove, and the first piezoelectric driving body may include: a first electrode which has ends fixed to both sides of the first groove and has a rectangular bar shape crossing the first groove; a first piezoelectric layer which is stacked on the first electrode; and a second electrode which is stacked on the piezoelectric layer.

The sensing apparatus may further include: a first reference magnetic field detection unit which includes a first reference piezoelectric driving body formed to have the same structure as the first piezoelectric driving body of the first magnetic field detection unit and made of the same material as the first piezoelectric driving body of the first magnetic field detection unit and is vibrated at the first natural frequency.

The sensing apparatus may further include: a second magnetic field detection unit which includes a second piezoelectric driving body formed on the substrate in the same direction as the first piezoelectric driving body and a second magnetostrictive layer stacked on one portion of the second piezoelectric driving body and is vibrated at a second vibration frequency changed from a second natural frequency in proportion to the magnitude of the external magnetic field in the second direction in parallel with the first and second magnetostrictive layers, wherein the control unit drives the first piezoelectric driving body and the second piezoelectric driving body with the constant AC voltage, calculates the magnitude of the external magnetic field in the second direction from the output voltage output from the second magnetic field detection unit to correct the magnitude of the external magnetic field in the first direction calculated from the output voltage output from the first magnetic field detection unit using the magnitude of the external magnetic field in the second direction.

The substrate may be provided with a first groove, the first piezoelectric driving body may include: a first electrode which has one end fixed to the substrate and the other end levitated in the state in which the other end is not supported to the substrate and has a bar shape; a first piezoelectric layer which is stacked on the first electrode; and a second electrode which is stacked on the piezoelectric layer, and the second piezoelectric driving body may include: a third electrode which has one end fixed to the substrate and the other end levitated in the state in which the other end is not supported to the substrate and has a bar shape; a second piezoelectric layer which is stacked on the third electrode; and a fourth electrode which is stacked on the second piezoelectric layer.

The sensing apparatus may further include: a first reference unit which includes a first reference piezoelectric driving body formed to have the same structure as the first piezoelectric driving body of the first magnetic field detection unit and made of the same material as the first piezoelectric driving body of the first magnetic field detection unit and is vibrated at a first natural frequency; and a second reference unit which includes a second reference piezoelectric driving body formed to have the same structure as the second piezoelectric driving body of the second magnetic field detection unit and made of the same material as the second piezoelectric driving body of the second magnetic field detection unit and is vibrated at a second natural frequency.

The substrate may be provided with a first groove, the first piezoelectric driving body may include: a first electrode which has ends fixed to both sides of the first groove and has a rectangular bar shape crossing the first groove; a first piezoelectric layer which is stacked on the first electrode; and a second electrode which is stacked on the piezoelectric layer, and the second piezoelectric driving body may include: a third electrode which has ends fixed to both sides of the first groove and has a rectangular bar shape crossing the first groove; a second piezoelectric layer which is stacked on the third electrode; and a fourth electrode which is stacked on the second piezoelectric layer.

The sensing apparatus may further include: a first reference unit which includes first reference piezoelectric driving body formed to have the same structure as the first piezoelectric driving body of the first magnetic field detection unit and made of the same material as the first piezoelectric driving body of the first magnetic field detection unit and is vibrated at a first natural frequency; and a second reference unit which includes a second piezoelectric driving body formed to have the same structure as the second piezoelectric driving body of the second magnetic field detection unit and made of the same material as the second piezoelectric driving body of the second magnetic field detection unit and is vibrated at a second natural frequency.

The flux concentrator may be formed on a side of the substrate.

The flux concentrator may have a rectangular shape.

The flux concentrator may have a trapezoidal shape in which a width adjacent to the second piezoelectric driving body is smaller than that of the opposite side thereof.

The substrate may be provided with a second groove and the flux concentrator may be formed on a side of the second groove.

The sensing apparatus may further include: a third magnetic field detection unit which includes a third piezoelectric driving body having a different direction from the first piezoelectric driving body formed on the substrate and a third magnetostrictive layer stacked on one portion of the third piezoelectric driving body and is vibrated at a third vibration frequency changed from a third natural frequency in proportion to a magnitude of an external magnetic field in a third direction, wherein a control unit drives the third piezoelectric driving body with a constant AC voltage and calculates the magnitude of the external magnetic field in the third direction from an output voltage output from the third magnetic field detection unit.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view of a magnetic field sensor according to a first preferred embodiment of the present invention;

FIG. 2 is a cross-sectional view taken along the line A-A1 of FIG. 1;

FIG. 3 is a cross-sectional view taken along the line B-B1 of FIG. 1;

FIG. 4 is a perspective view of a magnetic field sensor according to a second preferred embodiment of the present invention;

FIG. 5 is a cross-sectional view taken along the line A-A1 of FIG. 4;

FIG. 6 is a cross-sectional view taken along the line B-B1 of FIG. 4;

FIG. 7 is a perspective view of a magnetic field sensor according to a third preferred embodiment of the present invention;

FIG. 8 is a cross-sectional view taken along the line A-A1 of FIG. 7;

FIG. 9 is a cross-sectional view taken along the line B-B1 of FIG. 7;

FIG. 10 is a perspective view of a magnetic field sensor according to a fourth preferred embodiment of the present invention;

FIG. 11 is a cross-sectional view taken along the line A-A1 of FIG. 10;

FIG. 12 is a cross-sectional view taken along the line B-B1 of FIG. 10;

FIG. 13 is a structural view of a sensing apparatus using the magnetic field sensor according to the first preferred embodiment of the present invention;

FIG. 14 is a structural view of a sensing apparatus using the magnetic field sensor according to the second preferred embodiment of the present invention;

FIG. 15 is a structural view of a sensing apparatus using the magnetic field sensor according to the third preferred embodiment of the present invention;

FIG. 16 is a structural view of a sensing apparatus using the magnetic field sensor according to the fourth preferred embodiment of the present invention;

FIG. 17 is a structural view of a sensing apparatus using a magnetic field sensor according to a fifth preferred embodiment of the present invention;

FIG. 18 is a diagram for describing a principle of a flux concentrator of FIG. 17;

FIG. 19 is a structural view of a sensing apparatus using the magnetic field sensor according to a sixth preferred embodiment of the present invention;

FIG. 20 is a structural view of a sensing apparatus using the magnetic field sensor according to a seventh preferred embodiment of the present invention;

FIG. 21 is a structural view of a sensing apparatus using a magnetic field sensor according to an eighth preferred embodiment of the present invention;

FIG. 22 is a structural view of a sensing apparatus using a magnetic field sensor according to a ninth preferred embodiment of the present invention;

FIG. 23 is a structural view of a sensing apparatus using a magnetic field sensor according to a tenth preferred embodiment of the present invention;

FIG. 24 is a structural view of a sensing apparatus using a magnetic field sensor according to an eleventh preferred embodiment of the present invention; and

FIG. 25 is a structural view of a sensing apparatus using a magnetic field sensor according to a twelfth preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

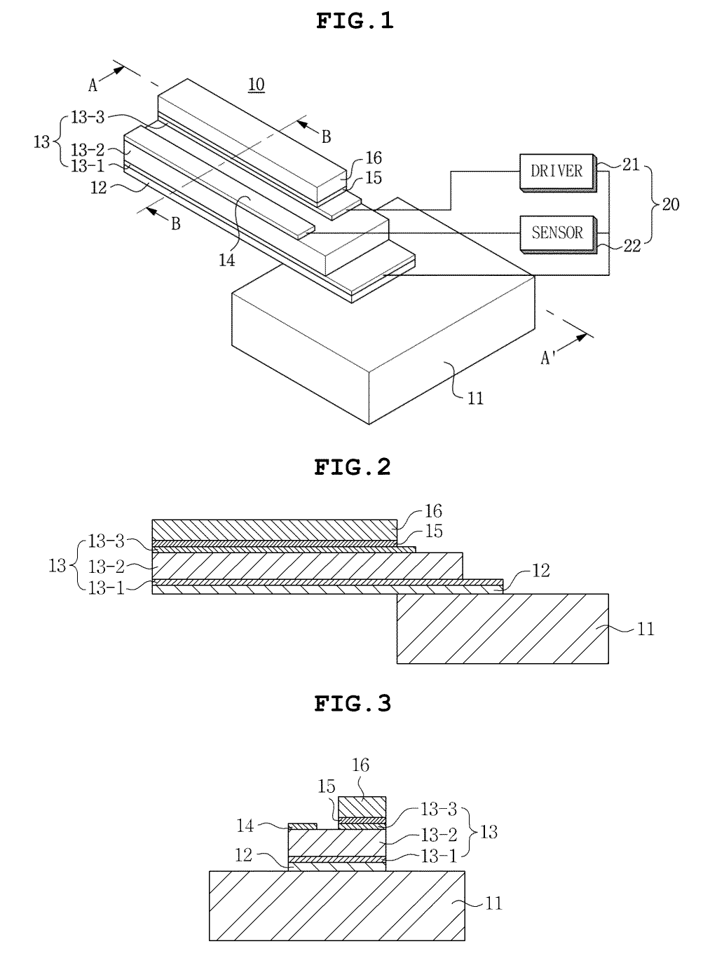

FIG. 1 is a perspective view of a magnetic field sensor according to a first preferred embodiment of the present invention, FIG. 2 is a cross-sectional view taken along the line A-A1 of FIG. 1, and FIG. 3 is a cross-sectional view taken along the line B-B1 of FIG. 1.

Referring to FIGS. 1 to 3, the magnetic field sensor according to the first preferred embodiment of the present invention is configured to include a magnetic field detection unit 10 and a control unit 20.

The magnetic field detection unit 10 vibrates a natural frequency having a constant magnitude as a vibration frequency by a driving of the control unit 20 when not being applied with an external magnetic field.

Unlike this, when being applied with the external magnetic field, the magnetic field detection unit 10 is vibrated as the vibration frequency changed from the natural frequency in proportion to a magnitude of the applied external magnetic field.

In this state, the magnetic field detection unit 10 generates an output voltage in proportion to the vibrating vibration frequency.

Such an operating magnetic field detection unit 10 includes a substrate 11, a first insulating layer 12, a piezoelectric driving body 13, a sensing electrode 14, a second insulating layer 15, and a magnetostrictive layer 16.

The substrate 11 has a flat plate shape and supports the piezoelectric driving body 13 having a cantilever shape and the magnetostrictive layer 14 stacked on the piezoelectric driving body 13.

The substrate 11 is illustrated as a quadrangular shape, but is not limited thereto and therefore may have various shapes.

The substrate 11 is a generally used semiconductor substrate and as a material forming the substrate 11, materials, such as silicon (Si), alumina (Al₂O₃), zirconium (ZrO₂), quartz, and silica (SiO₂), may be used.

Further, the first insulating layer 12 has a cantilever shape and protrudes on a side of the substrate 11 in the state in which one end thereof is fixed to the substrate 11 and the other end is not supported and has a rectangular bar shape.

The first insulating layer 12 provides a floating force to protrude on the side of the substrate 11 in the state in which a portion which is an approximately ⅓ to ¼ of the overall length of a long side is attached to the substrate 11 and the rest portion is not supported.

Meanwhile, the first insulating layer 12 supports the piezoelectric driving body 13 and electrically insulates the piezoelectric driving body 13 from the outside. In this case, a material used as the first insulating layer 12 may be silica (SiO₂). The first insulating layer 12 may be selectively provided. That is, the first insulating layer 12 may not also be provided.

Next, the piezoelectric driving body 13 has a cantilever shape and protrudes on a side of the substrate 11 in the state in which one end thereof is fixed to the substrate 11 and the other end is not supported and has a rectangular bar shape.

The piezoelectric driving body 13 includes a first electrode 13-1, a piezoelectric layer 13-2 which is formed on the first electrode 13-1 and is contracted and expanded when being applied with a predetermined voltage to generate a vertical driving force, and a second electrode 13-3 which is formed on the piezoelectric layer 13-2 and applies a predetermined voltage formed in the piezoelectric layer 13-2 between the second electrode 13-3 and the first electrode 13-1.

In this case, as an electrode material of the first electrode 13-1 or the second electrode 13-3, platinum (Pt), nickel (Ni), gold (Au), aluminum (Al), titanium (Ti), IrO₂, RuO₂, and the like may be used and any one of the combinations of the foregoing electrode materials may also be used.

The first electrode 13-1 or the second electrode 13-3 may be formed by methods, such as sputter, evaporation, and chemical vapor deposition.

Further, the piezoelectric layer 13-2 may be made of piezoelectric materials, such as PbTiO₃ (PTO), PbZrₓTi₁₋ₓO₃ (0.1<x<0.9) (PZT), [Pb(Mg_{y},Nb_{1-y})O₃]₁₋ₓ[PbTiO₃]ₓ (y˜0.33, 0.05<x<0.95) (PMNPT), (Pb_{1-y},La_{y})(Zrₓ,T₁₋ₓ)O₃ (0<y<0.1, 0.1<x<0.9) (PLZT), Pb(Nb_{y},Zrₓ,T_{1-y})O₃ (0<y<0.2, 0.2<x<0.8) (PNZT), AlN, and ZnO and may also be made of piezoelectric materials formed including at least one of elements, such as lead (Pb), zirconium (Zr), zinc (Zn), and titanium (Ti).

The piezoelectric layer 13-2 may be formed on the first electrode 13-1 by wet and dry methods.

Next, the sensing electrode 14 is formed on the piezoelectric driving body 13, in particular, may be formed on the piezoelectric layer 13-2 of the piezoelectric driving body 13 in parallel with the second electrode 13-3.

The sensing electrode 14 is used to measure a potential difference across the piezoelectric driving body 13, in particular, cooperates with the first electrode 13-1 of the piezoelectric driving body 13 to be used to measure the potential difference of the piezoelectric layer 13-2.

In this case, as the electrode material of the sensing electrode 14, platinum (Pt), nickel (Ni), gold (Au), aluminum (Al), titanium (Ti), IrO₂, RuO₂, and the like may be used and any one of the combinations of the foregoing electrode materials may also be used.

The sensing electrode 14 may be formed by the methods such as sputter, evaporation, and chemical vapor deposition.

Meanwhile, the sensing electrode 14 may be formed on the piezoelectric layer 13-2 in parallel with the second electrode 13-3, while the sensing electrode 14 may also be formed beneath the piezoelectric layer 13-2 in parallel with the first electrode 13-1.

The sensing electrode 14 is used to measure a potential difference across the piezoelectric driving body 13, in particular, cooperates with the second electrode 13-3 of the piezoelectric driving body 13 to be used to measure the potential difference of the piezoelectric layer 13-2.

Next, the second insulating layer 15 is formed on the piezoelectric driving body 13 and electrically insulates the magnetostrictive layer 16 from the piezoelectric driving body 13.

In this case, a material used as the second insulating layer 15 may be silica (SiO₂) and the like. The second insulating layer 15 may be selectively provided. That is, the second insulating layer 15 may not also be provided.

Next, the magnetostrictive layer 16 is stacked over the piezoelectric driving body 13 and is made of several materials of Fe—Si—B—C, Fe—Co—Si—B, Fe—Ni, Co—Ni, Co—Fe, Ni by electroplating.

In particular, the magnetostrictive layer 16 may be formed over the second electrode 13-3 of the piezoelectric driving body 13.

Meanwhile, the control unit 20 is driven to vibrate the magnetic field detection unit 10 at the natural frequency having a predetermined size.

When the magnetic field detection unit 10 is applied with an external magnetic field to detect the vibration frequency changed from the natural frequency in proportion to the magnitude of the external magnetic field, the control unit 20 calculates the magnitude of the external magnetic field using the vibration frequency.

To this end, the control unit 20 includes a driver 21 which applies the AC voltage to the first electrode 13-1 and the second electrode 13-3 of the piezoelectric driving body 13 to vertically vibrate the piezoelectric layer 13-2 at the natural frequency.

Further, the control unit 20 includes a sensor 22 which measures the potential difference of the piezoelectric layer 13-2 using the first electrode 13-1 and the sensing electrode 14 to detect the vibration frequency and then calculates a change amount of the vibration frequency changed from the detected natural frequency and then calculates the magnitude of the external magnetic field from the change amount of the calculated vibration frequency.

Meanwhile, when the sensing electrode 14 is disposed beneath the piezoelectric layer 13-2, the sensor 22 measures the potential difference between the second electrode 13-3 and the sensing electrode 14 to detect the magnitude of the external magnetic field.

An operation of the magnetic field sensor according to the first preferred embodiment of the present invention configured as described above will be described below.

First, the control unit 20 is driven to vibrate the magnetic field detection unit 10 at the natural frequency having a predetermined size by using the constant AC voltage.

Describing in more detail, the control unit 20 uses the driver 21 to apply the AC voltage to the first electrode 13-1 and the second electrode 13-3 of the piezoelectric driving body 13, thereby vertically vibrating the piezoelectric driving body 13.

That is, the driver 21 of the control unit 20 applies the AC voltage to the first electrode 13-1 and the second electrode 13-3 of the piezoelectric driving body 13 to repeatedly contract and expand the piezoelectric layer 13-2 in a width direction, that is, a longitudinal direction.

When the piezoelectric layer 13-2 is repeatedly contracted and expanded in the length direction, the piezoelectric layer 13-2 has a cantilever shape, that is, one portion thereof is fixed to the substrate 11 and the other portion thereof is levitated, such that the other portion thereof which is being levitated is vertically vibrated.

In this case, when the external magnetic field is applied, a length and a modulus of elasticity of the magnetostrictive layer 16 are changed and the change in the length of the magnetostrictive layer 16 leads to a change in the vibration characteristics of the piezoelectric driving body 13.

When the external magnetic field is applied, the size, modulus of elasticity, and stress of the magnetostrictive layer 16 is changed and thus the vibration frequency of the piezoelectric driving body 13, in particular, the piezoelectric layer 13-2 is changed.

The control unit 20 measures the voltage across the piezoelectric driving body 13, in particular, the piezoelectric layer 13-2 to find out the change in the vibration frequency and then calculates the magnitude of the external magnetic field using the change in the measured vibration frequency.

Describing in more detail, the sensor 22 of the control unit 20 measures the potential across the piezoelectric layer 13-2 of the piezoelectric driving body 13 using the sensing electrode 14 and the first electrode 13-1, finds out the change in the vibration frequency using the measured change in voltage, and then calculates the magnitude of the external magnetic field in proportion to the change amount of the vibration frequency.

Meanwhile, according to the first embodiment of the present invention, the sensing electrode 14 is separately present by being separated from the second electrode 13-3 of the piezoelectric driving body 13, but cooperates with the first electrode 13-1 by using the second electrode 13-3 as the sensing electrode to measure the voltage of the piezoelectric layer 13-2 and measure the magnitude of the external magnetic layer using the measured voltage.

Unlike this, the sensing electrode 14 cooperates with the second electrode 13-3 by using the first electrode 13-1 as the sensing electrode to measure the voltage of the piezoelectric layer 13-2 and measure the magnitude of the external magnetic layer using the measured voltage.

According to the preferred embodiment of the present invention as described above, the external magnetic field may be easily detected by using the simple structure in which the magnetostrictive layer 16 is stacked on the piezoelectric driving body 13.

Further, according to the preferred embodiment of the present invention, even though an electrode structure is simple, the change in the external magnetic field may be accurately detected.

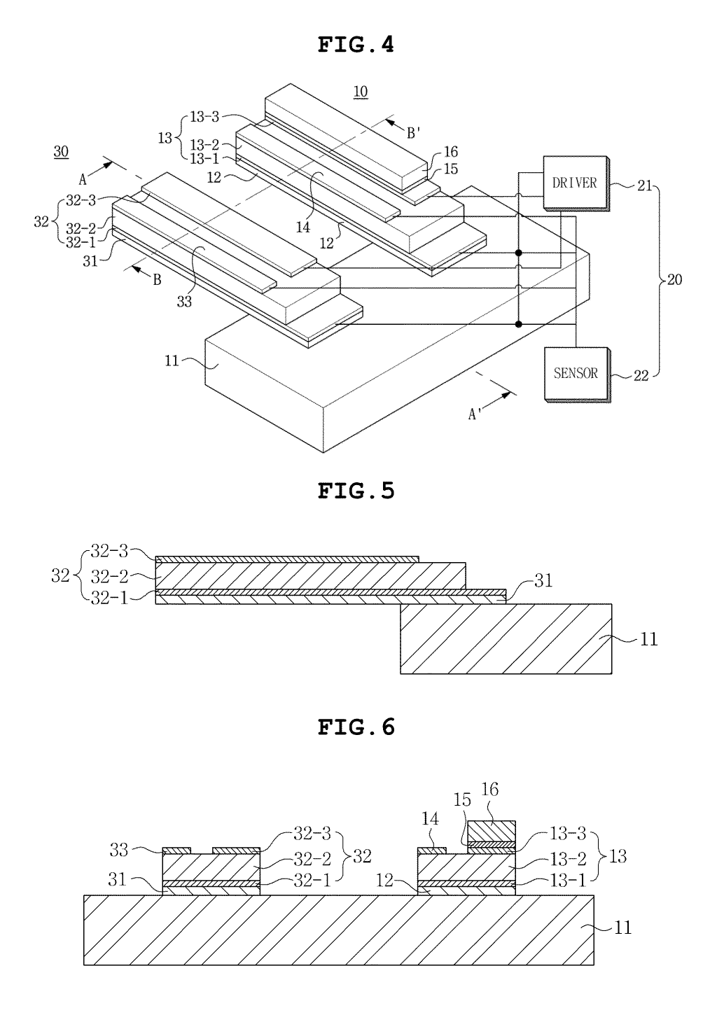

FIG. 4 is a perspective view of a magnetic field sensor according to a first preferred embodiment of the present invention, FIG. 5 is a cross-sectional view taken along the line A-A1 of FIG. 4, and FIG. 6 is a cross-sectional view taken along the line B-B1 of FIG. 4.

Referring to FIGS. 4 to 6, the magnetic field sensor according to a second preferred embodiment of the present invention further includes a reference unit 30, in addition to the magnetic field detection unit 10 and the control unit 20, compared with FIGS. 1 to 3. In this configuration, the magnetic field detection unit 10 is configured to include the substrate 11, the first insulating layer 12, the piezoelectric driving body 13, the sensing electrode 14, the second insulating layer 15, and the magnetostrictive layer 16.

The structure and the operation of the magnetic field detection unit 10 are the same as the magnetic field sensor according to the first preferred embodiment of the present invention and therefore the detailed description thereof will be omitted.

Meanwhile, the reference unit 30 is made of the same material as the magnetic field detection unit 10 and generally has the same structure other than the magnetostrictive layer 16 and a length thereof is formed to be slightly short. The reference unit 30 offsets an effect of increasing a frequency by making the overall thickness of a vibrator thin due to an absence of the magnetostrictive layer from an effect of reducing the frequency due to the contraction of a length of a vibrator, such that the reference unit 30 is vibrated at the same natural frequency as the vibrating vibration frequency when the external magnetic field is not applied to the magnetic field detection unit 10.

Further, the reference unit 30 may be formed in parallel with the magnetic field detection unit 10. Further, the reference unit 30 need not be parallel with the magnetic field detection unit 10.

The reference unit 30 is vibrated by being applied with the same AC voltage which is applied from the control unit 20 to the piezoelectric driving body 13, does not include the magnetostrictive layer so as not to be affected by the change in the external magnetic field, and is vibrated at the natural frequency determined by its own modulus of elasticity, density, residual stress, and the like.

In particular, the reference unit 30 is made of the same material as the magnetic field detection unit 10 and has the same structure other than the magnetostrictive layer 16, such that when the external magnetic field is not applied to the magnetic field detection unit 10, the reference unit 30 is vibrated at the same natural frequency as the vibrating vibration frequency.

Therefore, the control unit 20 compares the vibration frequency understood based on the potential difference measured by the magnetic field detection unit 10 with the natural frequency based on the potential difference measured by the reference unit 30 to find out the change in the vibration frequency of the piezoelectric driving body 13 and calculate the magnitude of the external magnetic field based on the change.

Unlike this, the magnetic field detection unit 10 may be operated by an electrical signal having a constant frequency generated from the reference unit 30 and in this state, the magnetic field detection unit 10 may measure the change in the external magnetic field based on the change in amplitude occurring by the external magnetic field or the voltage change in the signal.

The reference unit 30 is configured to include a reference insulating layer 31, a reference piezoelectric driving body 32, and a reference sensing electrode 33.

Further, the reference insulating layer 31 has a cantilever shape and protrudes on a side of the substrate 11 in the state in which one end thereof is fixed to the substrate 11 and the other end is not supported and has a rectangular bar shape.

The reference insulating layer 31 is formed in parallel with the first insulating layer 12.

The reference insulating layer 31 supports the reference piezoelectric driving body 32 and electrically insulates the reference piezoelectric driving body 32 from the outside. In this case, a material used as the reference insulating layer 31 may be silica (SiO₂) and the like. The reference insulating layer 31 may be selectively provided. That is, the reference insulating layer 31 may not also be provided.

Meanwhile, the reference piezoelectric driving body 32 has a cantilever shape and protrudes on a side of the substrate 11 in the state in which one end thereof is fixed to the substrate 11 and the other end is not supported and has a rectangular bar shape.

The reference piezoelectric driving body 32 is formed in parallel with the piezoelectric driving body 13.

The reference piezoelectric driving body 32 includes a first reference electrode 32-1, a reference piezoelectric layer 32-2 which is formed on the first reference electrode 32-1 and is contracted and expanded in a longitudinal direction when being applied with a predetermined voltage to generate a vertical driving force, and a second reference electrode 32-3 which is formed on the reference piezoelectric layer 32-2 and applies a predetermined voltage formed in the reference piezoelectric layer 32-2 between the second reference electrode 32-3 and the first reference electrodes 32-1.

In this case, as an electrode material of the first reference electrode 32-1 or the second reference electrode 32-3, platinum (Pt), nickel (Ni), gold (Au), aluminum (Al), titanium (Ti), IrO₂, RuO₂, and the like may be used and any one of the combinations of the foregoing electrode materials may also be used.

The first reference electrode 32-1 or the second reference electrode 32-3 may be formed by the methods, such as sputter, evaporation, and chemical vapor deposition.

Further, the reference piezoelectric layer 32-2 may be made of piezoelectric materials, such as PbTiO₃ (PTO), PbZrₓTi₁₋ₓO₃ (0.1<x<0.9) (PZT), [Pb(Mg_{y},Nb_{1-y})O₃]₁₋ₓ[PbTiO₃]ₓ (y˜0.33, 0.05<x<0.95) (PMNPT), (Pb_{1-y},La_{y})(Zrₓ,T₁₋ₓ)O₃ (0<y<0.1, 0.1<x<0.9) (PLZT), Pb(Nb_{y},Zrₓ,T_{1-y})O₃ (0<y<0.2, 0.2<x<0.8) (PNZT), AlN, and ZnO and may also be made of piezoelectric materials formed including at least one of elements, such as lead (Pb), zirconium (Zr), zinc (Zn), and titanium (Ti).

The reference piezoelectric layer 32-2 may be formed on the first reference electrode 32-1 or the second reference electrode 32-3 by a wet method and a dry method.

Next, the reference sensing electrode 33 is formed on the reference piezoelectric driving body 32, in particular, may be formed on the reference piezoelectric layer 32-2 of the piezoelectric driving body 32 in parallel with the second reference electrode 32-3.

The reference sensing electrode 33 is used to measure a potential difference across the reference piezoelectric driving body 32, in particular, cooperates with the first reference electrode 32-1 of the reference piezoelectric driving body 32 to be used to measure the potential difference of the reference piezoelectric layer 32-2.

In this case, as the electrode material of the reference sensing electrode 33, platinum (Pt), nickel (Ni), gold (Au), aluminum (Al), titanium (Ti), IrO₂, RuO₂, and the like may be used and any one of the combinations of the foregoing electrode materials may also be used.

The reference sensing electrode 33 may be formed by the methods such as sputter, evaporation, and chemical vapor deposition.

Meanwhile, the reference sensing electrode 33 may be formed on the reference piezoelectric layer 32-2 in parallel with the second reference electrode 32-3, while the reference sensing electrode 33 may also be formed beneath the reference piezoelectric layer 32-2 in parallel with the first reference electrode 32-1.

The reference sensing electrode 33 is used to measure a potential difference across the reference piezoelectric driving body 32, in particular, cooperates with the second reference electrode 32-3 of the reference piezoelectric driving body 32 to be used to measure the potential difference of the reference piezoelectric layer 32-2.

An operation of the magnetic field sensor according to the second preferred embodiment of the present invention configured as described above will be described below.

First, the control unit 20 applies the AC voltage to the first electrode 13-1 and the second electrode 13-3 of the piezoelectric driving body 13 to vertically vibrate the piezoelectric driving body 13 (the detailed operation thereof is the same as the first preferred embodiment of the present invention).

Simultaneously, the control unit 20 applies the AC voltage to the reference piezoelectric driving body 32 to vertically vibrate the piezoelectric driving body 32.

Describing in more detail, the driver 21 of the control unit 20 applies the AC voltage to the first reference electrode 32-1 and the second reference electrode 32-3 of the reference piezoelectric driving body 32 to repeatedly contract and expand the reference piezoelectric layer 32-2 in a longitudinal direction. In this case, since the reference piezoelectric layer 32-2 has a cantilever shape, that is, when one portion thereof is fixed to the substrate 11 and the other portion thereof is levitated, the other portion thereof which is levitated is vibrated vertically.

In this case, when the external magnetic field is applied, a length and a modulus of elasticity of the magnetostrictive layer 16 are changed and the change in the length of the magnetostrictive layer 16 leads to a change in the vibration characteristics of the piezoelectric driving body 13.

When the external magnetic field is applied, the size, modulus of elasticity, and stress of the magnetostrictive layer 16 are changed and thus the vibration frequency of the piezoelectric driving body 13, in particular, the piezoelectric layer 13-2 is changed.

The control unit 20 measures the piezoelectric driving body 13, in particular, the voltage across the piezoelectric layer 13-2 to find out the change in the vibration frequency (the detailed operation thereof is the same as the first preferred embodiment of the present invention).

Meanwhile, since the magnetostrictive layer is not formed, the reference piezoelectric driving body 32 is not affected by the external magnetic field and thus is vertically vibrated repeatedly depending on the natural frequency.

In this case, the control unit 20 measures the voltage across the reference piezoelectric driving body 32 to measure the natural frequency from the measured voltage across the reference piezoelectric driving body 32 and compares the vibration frequency calculated depending on the voltage across the piezoelectric layer 13-2 of the piezoelectric driving body 13 with the measured natural frequency to calculate the change amount of the vibration frequency.

Further, since the change amount of the vibration frequency is proportional to the magnitude of the external magnetic field, the control unit 20 calculates the magnitude of the external magnetic field using the change amount of the vibration frequency.

Meanwhile, according to the second embodiment of the present invention, the reference sensing electrode 33 is separately present by being separated from the reference second electrode 32-3 of the reference piezoelectric driving body 32, but cooperates with the first reference electrode 32-1 by using the second reference electrode 32-3 as the sensing electrode to measure the voltage of the reference piezoelectric layer 32-2 and measure the magnitude of the magnetic field using the measured voltage.

Unlike this, the reference sensing electrode 33 cooperates with the second reference electrode 32-3 by using the first reference electrode 32-1 as the sensing electrode to measure the voltage of the reference piezoelectric layer 32-2 and measure the magnitude of the magnetic field using the measured voltage.

According to the preferred embodiment of the present invention as described above, the external magnetic field may be easily detected by using the simple structure in which the magnetostrictive layer 16 is stacked on the piezoelectric driving body 13.

Further, according to the preferred embodiment of the present invention, even though an electrode structure is simple, the change in the external magnetic field may be accurately detected.

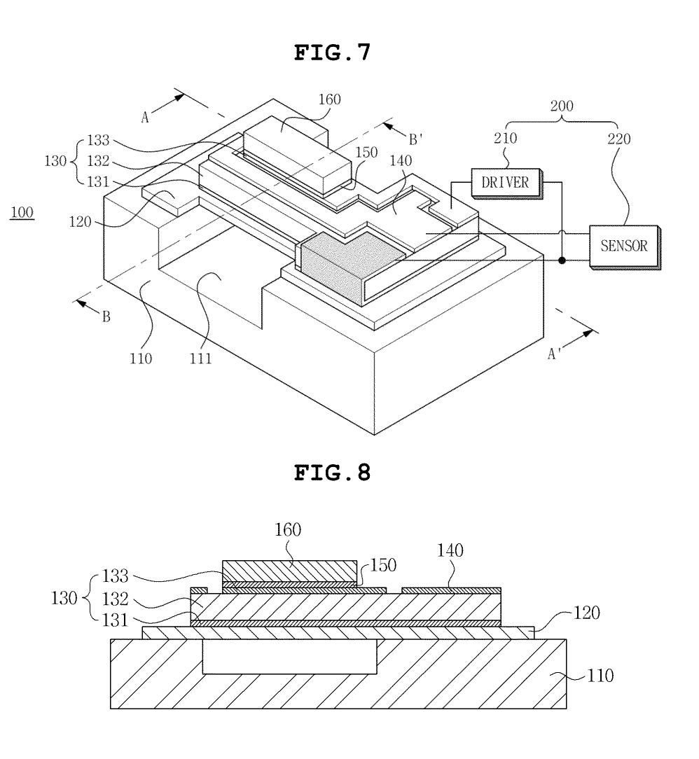

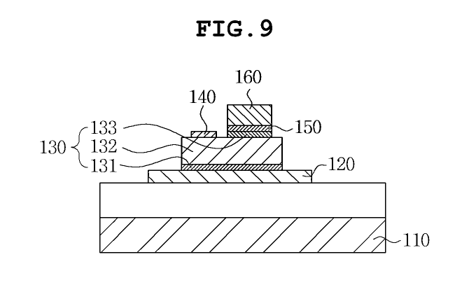

FIG. 7 is a perspective view of a magnetic field sensor according to a first preferred embodiment of the present invention, FIG. 8 is a cross-sectional view taken along the line A-A1 of FIG. 7, and FIG. 9 is a cross-sectional view taken along the line B-B1 of FIG. 7.

Referring to FIGS. 7 to 9, the magnetic field sensor according to a third preferred embodiment of the present invention is configured to include a magnetic field detection unit 100 and a control unit 200.

The magnetic field detection unit 100 vibrates a natural frequency having a constant magnitude as a vibration frequency by a driving of the control unit 200 when not being applied with an external magnetic field.

Unlike this, when being applied with the external magnetic field, the magnetic field detection unit 100 is vibrated as the vibration frequency changed from the natural frequency in proportion to a magnitude of the applied external magnetic field.

In this state, the magnetic field detection unit 100 generates and outputs an output voltage in proportion to the vibrating vibration frequency.

Such an operating magnetic field detection unit 100 includes a substrate 110, a first insulating layer 120, a piezoelectric driving body 130, a sensing electrode 140, a second insulating layer 150, and a magnetostrictive layer 160.

The substrate 110 has a quadrangular shape and is provided with a groove 111 and supports the piezoelectric driving body 130 which has ends fixed to both sides of the groove 111 and crosses the groove 111 and the magnetostrictive layer 160 which is stacked on the piezoelectric driving body 130.

The substrate 110 is a generally used semiconductor substrate and as a material forming the substrate 110, materials, such as silicon (Si), alumina (Al2O₃), zirconium (ZrO₂), quartz, and silica (SiO₂), may be used.

The groove 111 of the substrate 110 has, for example, a quadrangular shape and may be formed at a central portion of the substrate 110.

Next, the first insulating layer 120 has ends fixed to both sides of the groove 111 of the substrate 110 and has a rectangular bar shape which crosses the groove 111.

The first insulating layer 120 supports the piezoelectric driving body 130 and electrically insulates the piezoelectric driving body 130 from the outside. In this case, a material used as the first insulating layer 120 may be silica (SiO₂). The first insulating layer 120 may be selectively provided. That is, the first insulating layer 120 may not also be provided.

Meanwhile, the piezoelectric driving body 130 has a bar shape and is formed to have ends fixed to both sides of the groove 111 and cross the groove 111.

The piezoelectric driving body 130 includes a first electrode 131, a piezoelectric layer 132 which is formed on the first electrode 131 and is contracted and expanded when being applied with a predetermined voltage to generate a vertical driving force, and a second electrode 133 which is formed on the piezoelectric layer 132 and applies a predetermined voltage formed in the piezoelectric layer 132 between the second electrode 133 and the first electrode 131.

In this case, as an electrode material of the first electrode 131 or the second electrode 133, platinum (Pt), nickel (Ni), gold (Au), aluminum (Al), titanium (Ti), IrO₂, RuO₂, and the like may be used and any one of the combinations of the foregoing electrode materials may also be used.

The first electrode 131 or the second electrode 133 may be formed by the methods, such as sputter, evaporation, and chemical vapor deposition.

As illustrated, the first electrode 131 may be formed on the piezoelectric layer 132 via the side of the piezoelectric layer 132.

Further, the piezoelectric layer 132 may be made of piezoelectric materials, such as PbTiO₃ (PTO), PbZrₓTi₁₋ₓO₃ (0.1<x<0.9) (PZT), [Pb(Mg_{y},Nb_{1-y})O₃]₁₋ₓ[PbTiO₃]ₓ (y˜0.33, 0.05<x<0.95) (PMNPT), (Pb_{1-y},La_{y})(Zrₓ,T₁₋ₓ)O₃ (0<y<0.1, 0.1<x<0.9) (PLZT), Pb(Nb_{y},Zrₓ,T_{1-y})O₃ (0<y<0.2, 0.2<x<0.8) (PNZT), AlN, and ZnO and may also be made of piezoelectric materials formed including at least one of elements, such as lead (Pb), zirconium (Zr), zinc (Zn), and titanium (Ti).

The piezoelectric layer 132 may be formed on the first electrode 131 or the second electrode 133 by the methods, such as sputter, evaporation, and chemical vapor deposition.

Next, the sensing electrode 140 is formed on the piezoelectric driving body 130, in particular, may be formed on the piezoelectric layer 132 of the piezoelectric driving body 130 in parallel with the second electrode 133.

The sensing electrode 140 is used to measure a potential difference across the piezoelectric driving body 130, in particular, cooperates with the first electrode 131 of the piezoelectric driving body 130 to be used to measure the potential difference of the piezoelectric layer 132.

In this case, as the electrode material of the sensing electrode 140, platinum (Pt), nickel (Ni), gold (Au), aluminum (Al), titanium (Ti), IrO₂, RuO₂, and the like may be used and any one of the combinations of the foregoing electrode materials may also be used.

The sensing electrode 140 may be formed by the methods such as sputter, evaporation, and chemical vapor deposition.

Meanwhile, the sensing electrode 140 may be formed on the piezoelectric layer 132 in parallel with the second electrode 133, while the sensing electrode 140 may also be formed beneath the piezoelectric layer 132 in parallel with the lower electrode 131.

The sensing electrode 140 is used to measure the potential difference across the piezoelectric driving body 130, in particular, cooperates with the upper electrode 133 of the piezoelectric driving body 130 to be used to measure the potential difference of the piezoelectric layer 132.

Next, the second insulating layer 150 is formed on the piezoelectric driving body 130 and electrically insulates the magnetostrictive layer 160 from the piezoelectric driving body 130.

In this case, a material used as the second insulating layer 150 may be silica (SiO₂) and the like. The second insulating layer 150 may be selectively provided. That is, the second insulating layer 150 may not also be provided.

Next, the magnetostrictive layer 160 is stacked over the piezoelectric driving body 130 and is made of several materials of Fe—Si—B—C, Fe—Co—Si—B, Fe—Ni, Co—Ni, Co—Fe, Ni by the electroplating, the sputter, the evaporation, the chemical vapor deposition, or the like.

Meanwhile, the control unit 200 vertically vibrates the piezoelectric driving body 130 at the natural frequency and measures the potential difference between the upper and lower portions of the piezoelectric driving body 130 to be able to measure the magnitude of the external magnetic field.

To this end, the control unit 200 includes a driver 210 which applies the AC voltage to the first electrode 131 and the second electrode 133 of the piezoelectric driving body 130 to vertically vibrate the piezoelectric layer 132 and a sensor 220 which measures the potential differential of the piezoelectric layer 132 using the first electrode 131 and the sensing electrode 140 to measure the magnitude of the external magnetic field.

Meanwhile, when the sensing electrode 140 is disposed beneath the piezoelectric layer 132, the sensor 220 measures the potential difference between the first electrode 131 and the sensing electrode 140 to detect the magnitude of the external magnetic field.

An operation of the magnetic field sensor according to the third preferred embodiment of the present invention configured as described above will be described below.

First, the control unit 200 is driven to vibrate the magnetic field detection unit 100 at the natural frequency having a predetermined size by using the constant AC voltage.

Describing in more detail, the control unit 200 applies the AC voltage to the first electrode 131 and the second electrode 133 of the piezoelectric driving body 130 to vertically vibrate the piezoelectric driving body 130.

That is, the driver 210 of the control unit 200 applies the AC voltage to the first electrode 131 and the second electrode 133 of the piezoelectric driving body 130 to repeatedly contract and expand the piezoelectric layer 132 in a width direction, that is, a longitudinal direction.

As such, when the piezoelectric layer 132 is repeatedly contracted and expanded in the longitudinal direction, since the piezoelectric layer 132 has a bridge shape, that is, has both sides fixed to the substrate 110, a portion which is levitated is vertically vibrated.

In this case, when the external magnetic field is 0, the magnetostrictive layer 160 keeps an original size and is equally vibrated depending on the vibration of the piezoelectric driving body 130.

Unlike this, however, when the external magnetic field is generated, a contraction force to contract the length of the magnetostrictive layer 160 is generated and the contraction force affects the piezoelectric layer 132 of the mechanically connected piezoelectric driving body 130 to limit the amplitude of the vibration of the piezoelectric layer 132.

As such, when the magnetic field having a predetermined magnitude is applied from the outside, the contraction force is generated in the magnetostrictive layer 160, such that when the amplitude of the piezoelectric layer 132 is limited, the frequency of the piezoelectric layer 132 is changed.

In this case, the change amount of the vibration frequency is proportional to the magnitude of the external magnetic field. That is, when the change in the vibration frequency is measured, the magnitude of the external magnetic field may be calculated.

To this end, the control unit 200 uses the sensing electrode 140 to measure the voltage across the piezoelectric driving body 130.

Describing in more detail, the control unit 200 uses the sensing electrode 140 and the first electrode 131 of the piezoelectric driving body 130 to measure the voltage across the piezoelectric layer 132.

As such, when the control unit 200 measures the voltage across the piezoelectric layer 132 of the piezoelectric driving body 130, the control unit 200 measures the vibration frequency from the change amount of the voltage across the piezoelectric layer 132 and calculates the change amount of the measured vibration frequency.

Further, since the change amount of the vibration frequency is proportional to the magnitude of the external magnetic field, the control unit 200 calculates the magnitude of the external magnetic field using the change amount of the vibration frequency.

Meanwhile, according to the third preferred embodiment of the present invention, even though the sensing electrode 150 is separated from the second electrode 133 of the piezoelectric driving body 130, the voltage of the piezoelectric layer 132 is measured by using the second electrode 133 as the sensing electrode and the magnitude of the magnetic field may also be measured using the measured voltage.

Unlike this, the sensing electrode 150 cooperates with the second electrode 133 by using the first electrode 131 as the sensing electrode to measure the voltage of the piezoelectric layer 132 and measure the magnitude of the external magnetic layer using the measured voltage.

According to the preferred embodiment of the present invention as described above, the external magnetic field may be easily detected by using the simple structure in which the magnetostrictive layer 160 is stacked on the piezoelectric driving body 130.

Further, according to the preferred embodiment of the present invention, even though an electrode structure is simple, the change in the external magnetic field may be accurately detected.

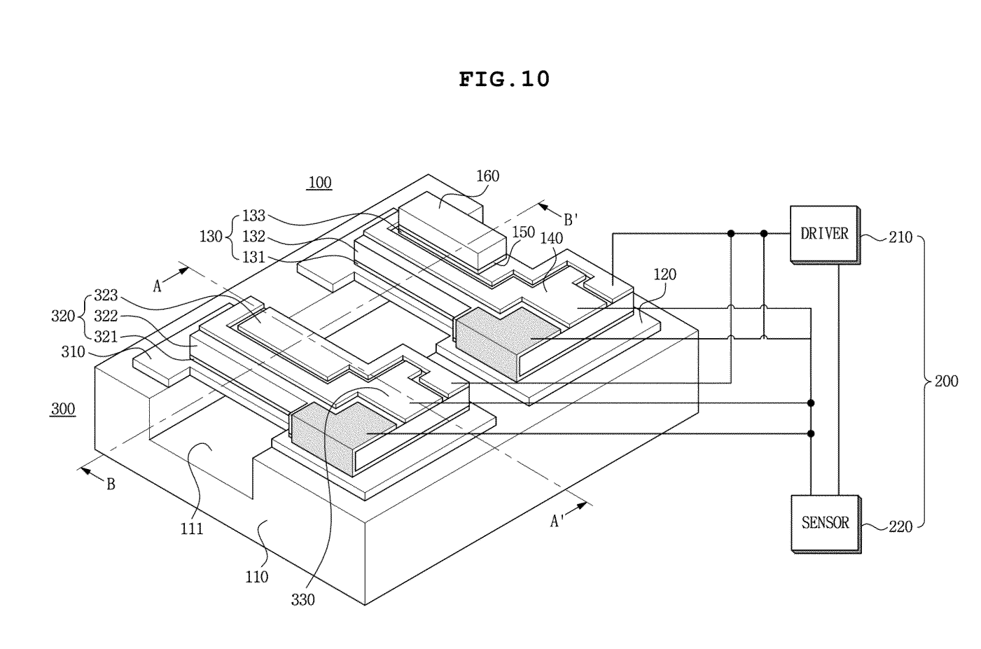

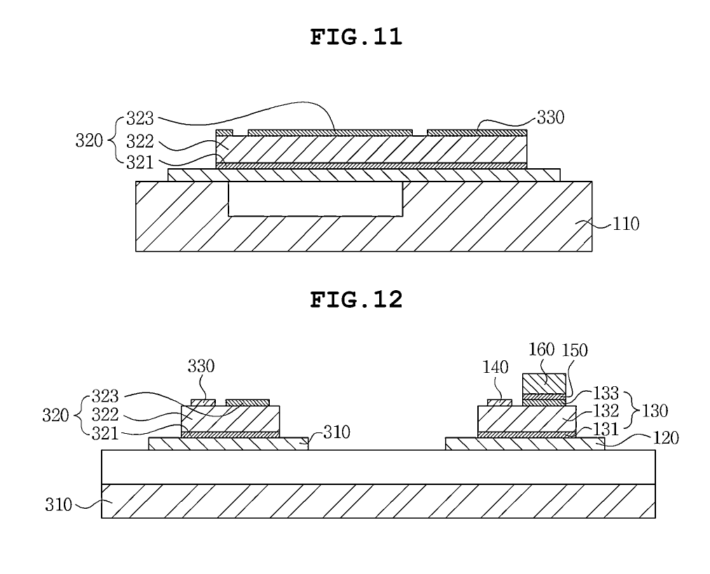

FIG. 10 is a perspective view of a magnetic field sensor according to a fourth preferred embodiment of the present invention, FIG. 11 is a cross-sectional view taken along the line A-A1 of FIG. 10, and FIG. 12 is a cross-sectional view taken along the line B-B1 of FIG. 10.

Referring to FIGS. 10 to 12, the magnetic field sensor according to the fourth preferred embodiment of the present invention further includes a reference unit 300, in addition to the magnetic field detection unit 100 and the control unit 200, compared with FIGS. 7 to 9. In this configuration, the magnetic field detection unit 100 is configured to include the substrate 110, the first insulating layer 120, the piezoelectric driving body 130, the sensing electrode 140, the second insulating layer 150, and the magnetostrictive layer 160 and the structure and the operation thereof are the same as those of the magnetic field sensor according to the third preferred embodiment of the present invention and therefore the detailed description thereof will be omitted.

Meanwhile, the reference unit 300 is made of the same material as the magnetic field detection unit 100 and generally has the same structure other than the magnetostrictive layer 160.

Further, the reference unit 300 may be formed in parallel with the magnetic field detection unit 100. Further, the reference unit 300 need not be parallel with the magnetic field detection unit 100.

The reference unit 300 is vibrated by being applied with the same AC voltage which is applied from the control unit 200 to the piezoelectric driving body 130, does not include the magnetostrictive layer so as not to be affected by the change in the external magnetic field, and is vibrated at the natural frequency determined by its own modulus of elasticity, density, residual stress, and the like.

In particular, the reference unit 300 is made of the same material as the magnetic field detection unit 100 and generally has the same structure other than the magnetostrictive layer 160 and a length thereof is formed to be slightly short. The reference unit 300 offsets an effect of increasing a frequency by making the overall thickness of a vibrator thin due to an absence of the magnetostrictive layer from an effect of reducing the frequency due to the contraction of a length of a vibrator, such that the reference unit 300 is vibrated at the same natural frequency as the vibrating vibration frequency when the external magnetic field is not applied to the magnetic field detection unit 100.

The reference unit 300 is vibrated by being equally applied with the AC voltage applied to the piezoelectric driving body 130 and is configured to include a reference insulating layer 310, a reference piezoelectric driving body 320, and a reference sensing electrode 330.

The reference insulating layer 310 has a bar shape and is formed to have ends fixed to both sides of the groove 111 and cross the groove 111.

The reference insulating layer 310 supports the reference piezoelectric driving body 320 and electrically insulates the reference piezoelectric driving body 320 from the outside. In this case, a material used as the reference insulating layer 310 may be silica (SiO₂) and the like. The reference insulating layer 310 may be selectively provided. That is, the reference insulating layer 310 may not also be provided.

Meanwhile, the reference piezoelectric driving body 320 has a bar shape and is formed to have ends fixed to both sides of the groove 111 and cross the groove 111.

The reference piezoelectric driving body 320 includes a first reference electrode 321, a reference piezoelectric layer 322 which is formed on the first reference electrode 321 and is contracted and expanded when being applied with a predetermined voltage to generate a vertical driving force, and a second reference electrode 323 which is formed on the reference piezoelectric layer 322 and applies a predetermined voltage formed in the reference piezoelectric layer 322 between the second reference electrode 323 and the first reference electrodes 321.

In this case, as an electrode material of the first reference electrode 321 or the second reference electrode 323, platinum (Pt), nickel (Ni), gold (Au), aluminum (Al), titanium (Ti), IrO₂, RuO₂, and the like may be used and any one of the combinations of the foregoing electrode materials may also be used.

The first reference electrode 321 or the second reference electrode 323 may be formed by the methods, such as sputter, evaporation, and chemical vapor deposition.

Further, the reference piezoelectric layer 322 may be made of piezoelectric materials, such as PbTiO₃ (PTO), PbZrₓTi₁₋ₓO₃ (0.1<x<0.9) (PZT), [Pb(Mg_{y},Nb_{1-y})O₃]₁₋ₓ[PbTiO₃]ₓ (y˜0.33, 0.05<x<0.95) (PMNPT), (Pb_{1-y},La_{y})(Zrₓ,T₁₋ₓ)O₃ (0<y<0.1, 0.1<x<0.9) (PLZT), Pb(Nb_{y},Zrₓ,T_{1-y})O₃ (0<y<0.2, 0.2<x<0.8) (PNZT), AlN, and ZnO and may also be made of piezoelectric materials formed including at least one of elements, such as lead (Pb), zirconium (Zr), zinc (Zn), and titanium (Ti).

The reference piezoelectric layer 322 may be formed on the first reference electrode 321 or the second reference electrode 323 by the methods, such as sputter, evaporation, and chemical vapor deposition.

As illustrated, the first reference electrode 321 may be formed on the reference piezoelectric layer 322 via the side of the reference piezoelectric layer 322.

Next, the reference sensing electrode 330 is formed on the reference piezoelectric driving body 320, in particular, may be formed on the reference piezoelectric layer 322 of the piezoelectric driving body 320 in parallel with the second reference electrode 323.

The reference sensing electrode 330 is used to measure a potential difference across the reference piezoelectric driving body 320, in particular, cooperates with the first reference electrode 321 of the reference piezoelectric driving body 320 to be used to measure the potential difference of the reference piezoelectric layer 320.

In this case, as the electrode material of the reference sensing electrode 330, platinum (Pt), nickel (Ni), gold (Au), aluminum (Al), titanium (Ti), IrO₂, RuO₂, and the like may be used and any one of the combinations of the foregoing electrode materials may also be used.

The reference sensing electrode 330 may be formed by the methods such as sputter, evaporation, and chemical vapor deposition.

Meanwhile, the reference sensing electrode 330 may be formed on the reference piezoelectric layer 322 in parallel with the second reference electrode 323, while the reference sensing electrode 330 may also be formed beneath the reference piezoelectric layer 322 in parallel with the first reference electrode 321.

The reference sensing electrode 330 is used to measure a potential difference across the reference piezoelectric driving body 322, in particular, cooperates with the second reference electrode 323 of the reference piezoelectric driving body 322 to be used to measure the potential difference of the reference piezoelectric layer 322.

An operation of the magnetic field sensor according to the fourth preferred embodiment of the present invention configured as described above will be described below.

First, the control unit 200 applies the AC voltage to the first electrode 131 and the second electrode 133 of the piezoelectric driving body 130 to vertically vibrate the piezoelectric layer 132.

Simultaneously, the control unit 200 applies the AC voltage to the first reference electrode 321 and the second reference electrode 323 of the reference piezoelectric driving body 320 to vertically vibrate the reference piezoelectric layer 322.

In this case, when the external magnetic field is 0, the magnetostrictive layer 160 keeps an original magnitude and is equally vibrated depending on the vibration of the piezoelectric driving body 130, while when the external magnetic field is generated, the contraction force to contract the length of the magnetostrictive layer 160 is generated, and at the same time, the modulus of elasticity of the magnetostrictive layer 160 is changed. The generation of the contraction force and the change in the modulus of elasticity of the magnetostrictive layer 160 also affects the piezoelectric layer 132 of the mechanically connected piezoelectric driving body 130 to change the natural frequency of the vibration of the piezoelectric layer 132.

In this case, the control unit 200 uses the sensing electrode 140 to measure the voltage across the piezoelectric driving body 130.

Simultaneously, the control unit 200 uses the reference sensing electrode 330 to measure the voltage across the reference piezoelectric driving body 320.

As such, when the control unit 200 measures the voltage across the piezoelectric layer 132 of the piezoelectric driving body 130 and measures the voltage across the reference piezoelectric driving body 320, the control unit 200 measures the natural frequency from the change amount of the measured voltage across the reference piezoelectric driving body 320 and compares the vibration frequency depending on the change in the voltage across the piezoelectric layer 132 of the piezoelectric driving body with the measured natural frequency to calculate the change amount of the vibration frequency.

Further, since the change amount of the vibration frequency is proportional to the magnitude of the external magnetic field, the control unit 200 calculates the magnitude of the external magnetic field using the change amount of the vibration frequency.

Unlike this, the control unit 200 drives the reference unit 300 and operates the magnetic field detection unit 100 with the electric signal having the constant frequency generated from the reference unit 300 and in this state, the magnetic field detection unit 100 may measure the change in the external magnetic field based on the change in amplitude occurring by the external magnetic field or the voltage change in the signal.

Meanwhile, according to the fourth preferred embodiment of the present invention, even though the reference sensing electrode 330 is separated from the second reference electrode 323 of the reference piezoelectric driving body 320, the voltage of the reference piezoelectric layer 322 may be measured by using the second reference electrode 323 as the reference sensing electrode.

According to the preferred embodiment of the present invention as described above, the external magnetic field may be easily detected by using the simple structure in which the magnetostrictive layer 160 is stacked on the piezoelectric driving body 130.

Further, according to the preferred embodiment of the present invention, even though an electrode structure is simple, the change in the external magnetic field may be accurately detected.

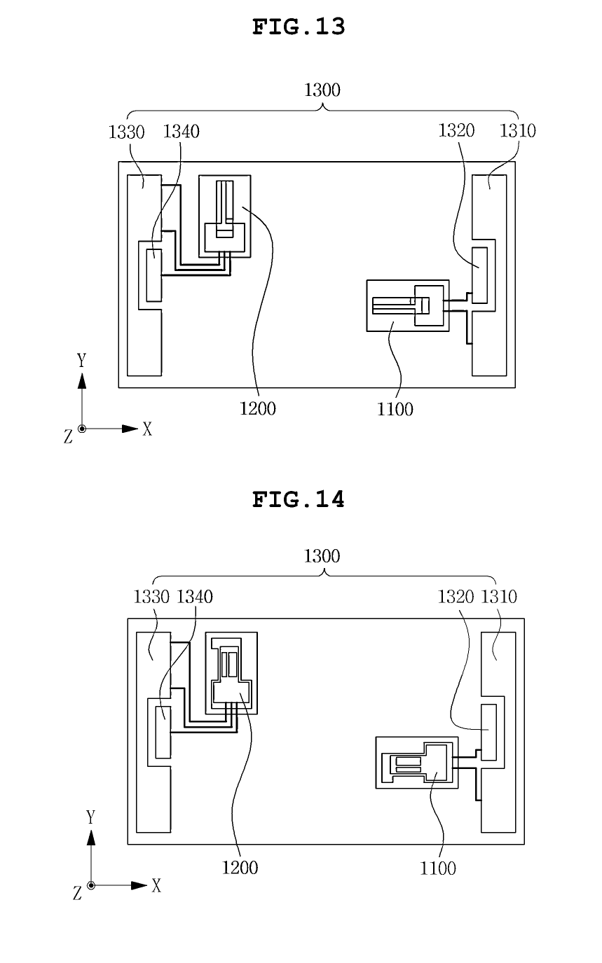

FIG. 13 is a structural view of a sensing apparatus using the magnetic field sensor according to the first preferred embodiment of the present invention.

Referring to FIG. 13, a sensing apparatus using the magnetic field sensor according to the first preferred embodiment of the present invention includes a first axis magnetic field detection unit 1100, a second axis magnetic field detection unit 1200, and a control unit 1300. Herein, the first axis and the second axis form a right angle to each other.

A structure of the first axis magnetic field detection unit 1100 and the second axis magnetic field detection unit 1200 is the same as the magnetic field detection unit illustrated in FIGS. 1 to 3 and only the directions of the first axis magnetic field detection unit 1100 and the second axis magnetic field detection unit 1200 form a right angle to each other.

Unlike this, the structure of the first axis magnetic field detection unit 1100 and the second axis magnetic field detection unit 1200 may be the same as that of the magnetic field detection unit illustrated in FIGS. 7 to 9 and only of the directions of the first axis magnetic field detection unit 1100 and the second axis magnetic field detection unit 1200 may form a right angle to each other and the structure thereof is illustrated in FIG. 14.

As such, as the directions of the first axis magnetic field detection unit 1100 and the second axis magnetic field detection unit 1200 form a right angle to each other, the first axis magnetic field detection unit 1100 may detect the change in an X-axis external magnetic field since the magnetostrictive layer is put on an X axis and the second axis magnetic field detection unit 1200 may detect the change in a Y-axis external magnetic field since the magnetostrictive layer is put on a Y axis.

The detailed structure and operation of the first axis magnetic field detection unit 1100 and the second axis magnetic field detection unit 1200 are described in FIGS. 1 to 3 in advance and the detailed description thereof will be omitted.

Meanwhile, the control unit 1300 includes a first driver 1310 which drives the first axis magnetic field detection unit 1100 and a second driver 1330 which drives the second axis magnetic field detection unit 1200. The operation of the first driver 1310 and the second driver 1330 is the same as the driver illustrated in the first preferred embodiment of the present invention and the driver illustrated in the third preferred embodiment of the present invention and therefore the operation description thereof will be omitted.

Further, the control unit 1300 includes a first sensor 1320 which detects the potential difference from the first axis magnetic field detection unit 1100, detects the vibration frequency using the detected potential difference, and then uses the change amount of the detected vibration frequency to detect the magnitude of the external magnetic field and a second sensor 1340 which detects the potential difference from the first sensor 1320 and the second axis magnetic field detection unit 1200, uses the detected potential difference to detect the vibration frequency, and then uses the change amount of the detected vibration frequency to detect the magnitude of the external magnetic field.

Describing the operation of the sensing apparatus, the control unit 1300 uses the first driver 1310 to drive the first magnetic field detection unit 1100.

Further, the control unit 1300 uses the first sensor 1320 to detect the potential difference from the first axis magnetic field detection unit 1100, uses the detected potential difference to detect the vibration frequency, and then uses the change amount of the detected vibration frequency to detect the magnitude of the external magnetic field in the first axis direction.

Meanwhile, the control unit 1300 uses the second driver 1330 to drive the second magnetic field detection unit 1200.

Further, the control unit 1300 uses the second sensor 1340 to detect the potential difference from the second axis magnetic field detection unit 1200, uses the detected potential difference to detect the vibration frequency, and then uses the change amount of the detected vibration frequency to detect the magnitude of the external magnetic field in the second axis direction.

Meanwhile, FIG. 14 is a structural view of a sensing apparatus using the magnetic field sensor according to the second preferred embodiment of the present invention.

The structure of FIG. 14 is the same as that of FIG. 13 except that in the structure of FIG. 13 the shape of the vibrator is changed from the cantilever structure to the bridge structure. The bridge structure is illustrated in detail in FIGS. 7 to 9. The operation of the sensing apparatus and the method for measuring a magnetic field depending on the structure of FIG. 14 are the same as the structure of FIG. 13, and therefore the operation process thereof will be omitted.

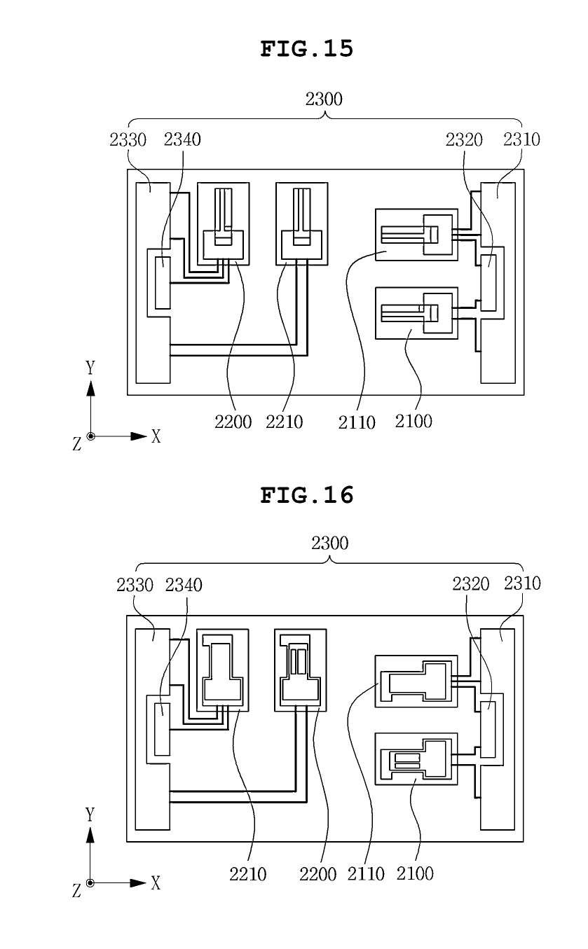

FIG. 15 is a structural view of a sensing apparatus using the magnetic field sensor according to the third preferred embodiment of the present invention.

Referring to FIG. 15, the sensing apparatus using the magnetic field sensor according to the third preferred embodiment of the present invention includes a first axis magnetic field detection unit 2100, a first axis reference unit 2110, a second axis magnetic field detection unit 2200, a second axis reference unit 2210, and a control unit 2300.

A structure of the first axis magnetic field detection unit 2100 and the second axis magnetic field detection unit 2200 is the same as the magnetic field detection unit illustrated in FIGS. 4 to 6 and only the directions of the first axis magnetic field detection unit 2100 and the second axis magnetic field detection unit 2200 form a right angle to each other.

Further, the structure of the first axis reference unit 2110 and the second axis reference unit 2210 is the same as that of the reference unit illustrated in FIGS. 4 to 6 and only the directions thereof form a right angle to each other.

As such, as the first axis magnetic field detection unit 2100 and the second axis magnetic field detection unit 2200 form a right angle to each other, the first axis magnetic field detection unit 2100 may detect the change in an X-axis external magnetic field since the magnetostrictive layer is put on an X axis and the second axis magnetic field detection unit 2200 may detect the change in a Y-axis external magnetic field since the magnetostrictive layer is put on a Y axis.

The detailed structure and operation of the first axis magnetic field detection unit 2100 and the second axis magnetic field detection unit 2200 are described in FIGS. 4 to 6 in advance and the detailed description thereof will be omitted.

The detailed structure and operation of the first axis magnetic field detection unit 2110 and the second axis magnetic field detection unit 2210 are described in FIGS. 4 to 6 in advance and the detailed description thereof will be omitted.

Meanwhile, the control unit 2300 includes a first driver 2310 which drives the first axis magnetic field detection unit 2100 and the first reference unit 2110.

Further, the control unit 2300 includes a second driver 2330 which drives the second axis magnetic field detection unit 2200 and the second reference unit 2210. The operation of the first driver 2310 and the second driver 2330 is the same as the driver illustrated in FIGS. 4 to 6 and therefore the operation description thereof will be omitted.

Further, the control unit 2300 includes a first sensor 2320 which detects the potential difference from the first axis magnetic field detection unit 2100, uses the detected potential difference to detect the vibration frequency, detects the potential difference from the first reference unit 2110 based on the detected vibration frequency, uses the detected potential difference to detect the natural frequency, and calculates the change amount of the vibration frequency using the natural frequency to detect the magnitude of the external magnetic field in the first axis direction.

The control unit 2300 includes a second sensor 2340 which detects the potential difference from the second axis magnetic field detection unit 2200, uses the detected potential difference to detect the vibration frequency, detects the potential difference from the second reference unit 2210 based on the detected vibration frequency, uses the detected potential difference to detect the natural frequency, and calculates the change amount of the vibration frequency using the natural frequency to detect the magnitude of the external magnetic field in the second axis direction.

Describing the operation of the sensing apparatus, the control unit 2300 uses the first driver 2310 to drive the first magnetic field detection unit 2100 and the first reference unit 2110.

Further, the control unit 2300 uses the first sensor 2320 to detect the potential difference from the first axis magnetic field detection unit 2100, uses the detected potential difference to detect the vibration frequency, detects the potential difference from the first reference unit 2110 based on the detected vibration frequency, uses the detected potential difference to detect the natural frequency, and calculates the change amount of the vibration frequency using the natural frequency to detect the magnitude of the external magnetic field in the first axis direction.

Meanwhile, the control unit 2300 uses the second driver 2330 to drive the second magnetic field detection unit 2200 and the second reference unit 2210.

Further, the control unit 2300 uses the second sensor 2340 to detect the potential difference from the second axis magnetic field detection unit 2200, uses the detected potential difference to detect the vibration frequency, detects the potential difference from the second reference unit 2210 based on the detected vibration frequency, uses the detected potential difference to detect the natural frequency, and calculates the change amount of the vibration frequency using the natural frequency to detect the magnitude of the external magnetic field in the second axis direction.

Meanwhile, FIG. 16 is a structural view of a sensing apparatus using the magnetic field sensor according to the fourth preferred embodiment of the present invention.

The structure of FIG. 16 is the same as that of FIG. 15 except that in the structure of FIG. 13 the shape of the vibrator is changed from the cantilever structure to the bridge structure. The bridge structure is illustrated in detail in FIGS. 10 to 12. The operation of the sensing apparatus and the method for measuring a magnetic field depending on the structure of FIG. 16 are the same as the structure of FIG. 15, and therefore the operation process thereof will be omitted.

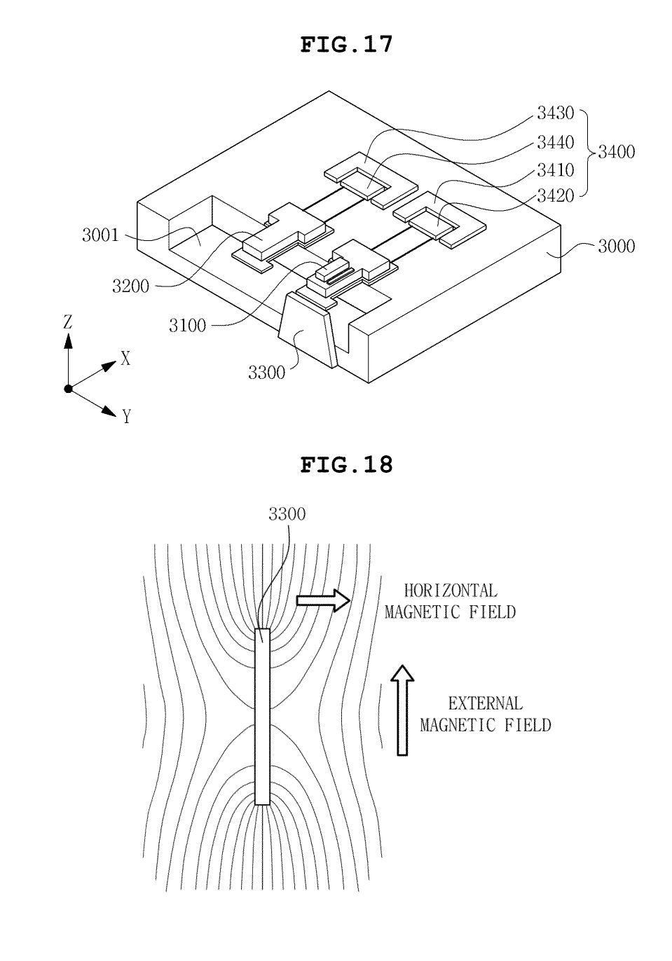

FIG. 17 is a structural view of a sensing apparatus using a magnetic field sensor according to a fifth preferred embodiment of the present invention.

Referring to FIG. 17, a sensing apparatus using the magnetic field sensor according to a fifth preferred embodiment of the present invention includes a first magnetic field detection unit 3100, a first reference unit 3200, a flux concentrator 3300, and a control unit 3400. Herein, the magnetic field detection unit 3100 and the reference unit 3200 has the same structure and direction excepting whether the magnetostrictive layer is present and are in parallel with the ground.

The structure of the first magnetic field detection unit 3100 and the first reference unit 3200 is the same as that of the magnetic field detection unit illustrated in FIGS. 4 to 6 and the detailed structure and operation thereof are described in advance and therefore the description thereof will be omitted.

Meanwhile, the flux concentrator 3300 has a thin plate shape made of a soft magnetic material and is formed on the side of the substrate 3000 in parallel with the ground to be vertically mounted to the ground.

In this case, the side of the substrate 3000 may be formed to have an acute angle of 60 to 90° to the ground.

Further, in the substrate 3000, to secure the driving space of the first magnetic field detection unit 3100 and the first reference unit 3200 having the cantilever shape, as illustrated, a groove 3001 for a driving space is formed under the first magnetic field detection unit 3100 and the first reference unit 3200.

Therefore, a portion of the flux concentrator 3300 is attached to the side of the substrate 3000 and thus is fixedly supported.

When the flux concentrator 3300 is exposed to the external magnetic field in a parallel direction as illustrated in FIG. 18, the horizontal magnetic field is generated around both ends of the flux concentrator 3300.

As the result, one portion of the flux concentrator 3300 is disposed near the first magnetic field detection unit 3100, and thus the flux concentrator 3300 induces the first directional (herein, z-axis directional) magnetic field component vertical to the ground so as to affect the first magnetic field detection unit 3100.

The flux concentrator 3300 may have a diamond shape in which a width of one portion adjacent to the first magnetic field detection unit 3100 is small, a rectangular plate shape, or a triangular shape.

Meanwhile, the control unit 3400 includes a first driver 3410 which drives the first magnetic field detection unit 3100.

Further, the control unit 3400 includes a second driver 3430 which drives the first reference unit 3200. The operation of the first driver 3410 and the second driver 3430 is the same as that of the driver illustrated in FIGS. 4 to 6 and therefore the operation description and the operation thereof will be omitted.

The control unit 3400 detects the potential difference from the first magnetic field detection unit 3100, uses the detected potential difference to detect the vibration frequency, and detects the magnitude of the external magnetic field which is a sum of the external magnetic fields in the first direction (herein, z-axis direction) and the second direction, by calculating the change amount of the vibration frequency using the natural frequency.

When the first magnetic field detection unit 3100 of the sensing apparatus using the magnetic field sensor according to the fifth preferred embodiment of the present invention is driven by the first driver 3410 of the control unit 3400, the first magnetic field detection unit 3100 generates and outputs, through the flux concentrator 3300, the voltage having the changed vibration frequency in proportion to the magnitude of the magnetic field which is a sum of the magnitude of the magnetic field in the second direction with the magnitude of the magnetic field in the first direction vertical to the ground.

Further, when the first reference unit 3200 is driven by the second driver 3430 of the control unit 3400, the first reference unit generates and outputs the voltage having the changed vibration frequency in proportion to the magnitude of the external magnetic field with respect to the second direction (X axis or Y axis).

As such, when the first magnetic field detection unit 3100 generates and outputs, through the flux concentrator 3300, the voltage having the changed vibration frequency in proportion to the magnitude of the magnetic field which is a sum of the magnitude of the magnetic field in the second direction with the magnitude of the magnetic field in the first direction vertical to the ground, the first sensor 3420 of the control unit 3400 uses the voltage output from the first magnetic field detection unit 3100 to detect the magnitude of the external magnetic field overlapping the external magnetic fields in the first and second directions.

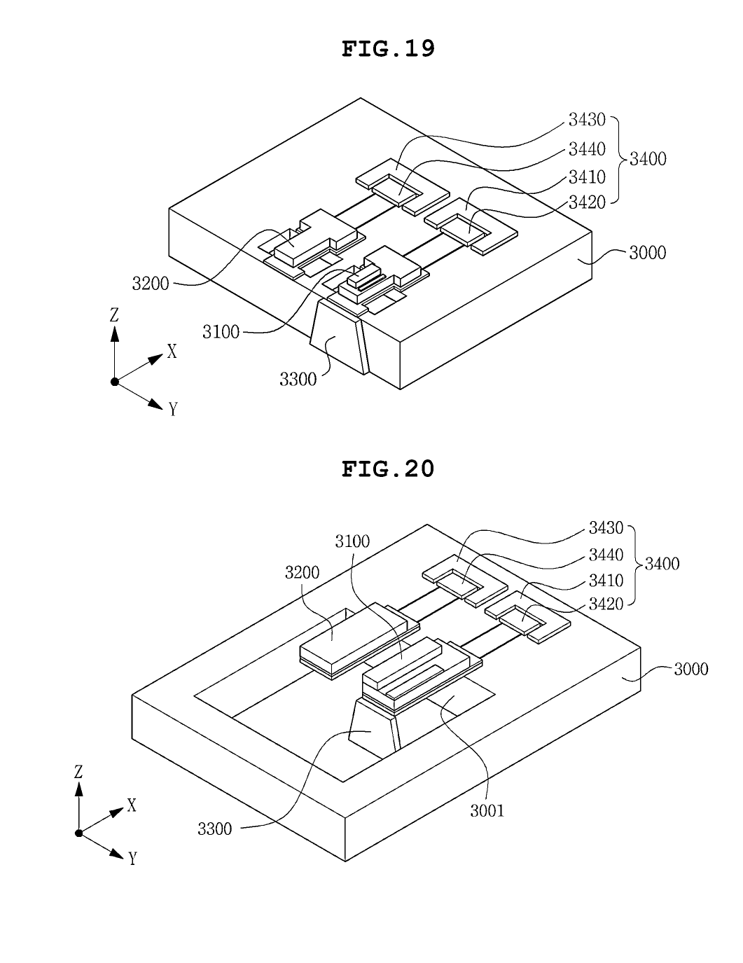

Meanwhile, FIG. 19 is a structural view of a sensing apparatus using a magnetic field sensor according to a sixth preferred embodiment of the present invention.

The structure of FIG. 19 is the same as that of FIG. 17 except that in the structure of FIG. 13 the shape of the vibrator is changed from the cantilever structure to the bridge structure. The bridge structure is illustrated in detail in FIGS. 10 to 12. The operation of the sensing apparatus and the method for measuring a magnetic field depending on the structure of FIG. 17 are the same as the structure of FIG. 19, and therefore the operation process thereof will be omitted.

Next, FIG. 20 illustrates a sensing apparatus according to a seventh preferred embodiment of the present invention and is different in that the flux concentrator 3300 is disposed on the side of the groove 3001 for security of space and driving space, not on the space of the substrate 3000.

The groove 3001 for security of space and driving space is formed to be collapsed in a portion of the substrate 3000 and the side contacting the first magnetic field detection unit 3100 is formed to have an acute angle of 60 to 90° with respect to the ground.

The groove 3001 for security of space and driving space provides a space in which the flux concentrator 3300 may be disposed and provides the driving space in which the first magnetic field detection unit 3100 and the first reference unit 3200 may be driven.

The operation of the sensing apparatus according to the seventh preferred embodiment of the present invention is similar to the fifth preferred embodiment of the present invention and therefore the detailed description thereof will be omitted.

Herein, the magnetic field detection unit illustrated in FIG. 20 is the same as the magnetic field detection unit illustrated in FIGS. 4 to 6.

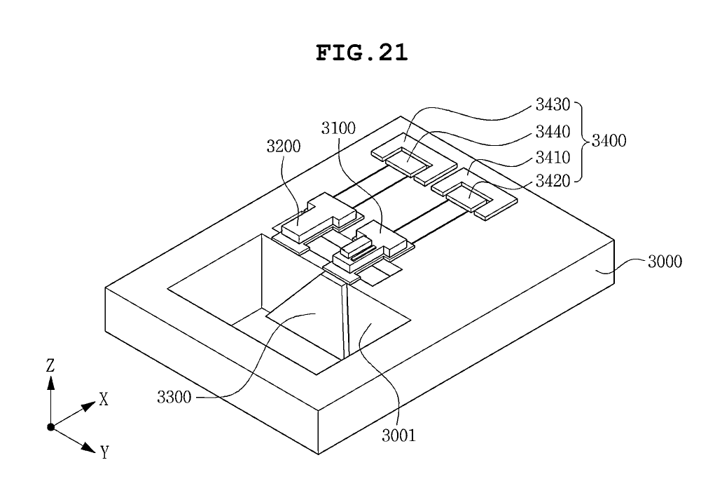

Next, FIG. 21 is a structural view of a sensing apparatus using a magnetic field sensor according to an eighth preferred embodiment of the present invention.

The structure of FIG. 21 is the same as that of FIG. 20 except that in the structure of FIG. 20 the shape of the vibrator is changed from the cantilever structure to the bridge structure. The bridge structure is illustrated in detail in FIGS. 10 to 12. The operation of the sensing apparatus and the method for measuring a magnetic field depending on the structure of FIG. 20 are the same as the structure of FIG. 20, and therefore the operation process thereof will be omitted.

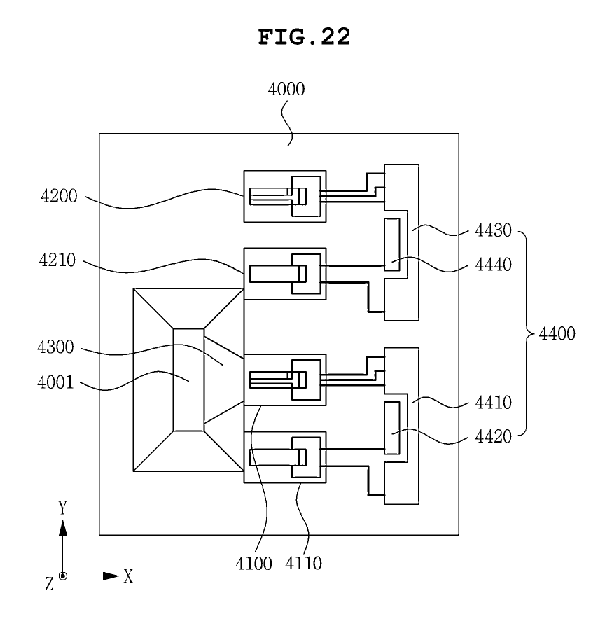

FIG. 22 is a structural view of a sensing apparatus using a magnetic field sensor according to a ninth preferred embodiment of the present invention;

Referring to FIG. 22, a sensing apparatus using a magnetic field sensor according to a ninth preferred embodiment of the present invention includes a first magnetic field detection unit 4100, a first reference unit 4110, a second magnetic field detection unit 4200, a second reference unit 4210, a flux concentrator 4300, and a control unit 4400.

Herein, the first magnetic field detection unit 4100 and the second magnetic field detection unit 4200 have the same structure and direction and are parallel with the ground.

Further, the structure of the first reference unit 4110 has the same as that of the first magnetic field detection unit 4100 other than a material and a magnetostrictive layer and the structure of the second reference unit 4210 has the same as that of the second magnetic field detection unit 4200 other than the material and the magnetostrictive layer.

The first reference unit 4110 and the second reference unit 4210 have the same structure and direction and are parallel with the ground. However, the first reference unit 4110 and the second reference unit 4210 have different directions and are not necessarily parallel with the ground.

The structure of the first magnetic field detection unit 4100 and the second magnetic field detection unit 4200 is the same as that of the magnetic field detection unit illustrated in FIGS. 4 to 6 and the detailed structure and operation thereof are described in advance and therefore the description thereof will be omitted.

Meanwhile, the structure of the first reference unit 4110 and the second reference unit 4210 is the same as that of the reference unit illustrated in FIGS. 4 to 6.

Meanwhile, the flux concentrator 4300 has a thin plate shape made of a soft magnetic material and is formed on the side of the groove 4001 of the substrate 4000 parallel with the ground to be vertically mounted on the ground.

In this case, the side of the groove 4001 of the substrate 4000 may be formed to have an acute angle of 60 to 90° to the ground.

When the flux concentrator 4300 is exposed to the external magnetic field in a parallel direction (Z-axis direction which is a direction vertical to the ground), the horizontal magnetic field is generated around both ends of the flux concentrator 4300.

As the result, one portion of the flux concentrator 4300 is disposed near the first magnetic field detection unit 4100, and thus the flux concentrator 4300 induces the first directional (herein, z-axis directional) magnetic field component vertical to the ground so as to affect the first magnetic field detection unit 4100.

The flux concentrator 4300 may have a diamond shape in which a width of one portion adjacent to the first magnetic field detection unit 4100 is small, a rectangular plate shape, or a triangular shape.

Further, the flux concentrator 4300 is formed on the side of the substrate 4000 parallel with the ground to be vertically mounted on the ground.

Meanwhile, the control unit 4400 includes a first driver 4410 which drives the first magnetic field detection unit 4100 and the first reference unit 4110.

Further, the control unit 4400 includes a second driver 4430 which drives the second magnetic field detection unit 4200 and the second reference unit 4210. The operation of the first driver 4210 and the second driver 4430 is the same as the driver illustrated in FIGS. 4 to 6 and therefore the operation description thereof will be omitted.

Further, the control unit 4400 includes a first sensor 4420 which detects the potential difference from the first magnetic field detection unit 4100, uses the detected potential difference to detect the vibration frequency, detects the potential difference from the first reference unit 4110 based on the detected vibration frequency, uses the detected potential difference to detect the natural frequency, and calculates the change amount of the vibration frequency using the natural frequency to detect the magnitude of the external magnetic field in the first axis direction.

The control unit 4400 includes a second sensor 4440 which detects the potential difference from the second magnetic field detection unit 4200, detects the vibration frequency using the detected potential difference, detects the potential difference from the second reference unit 4210 based on the detected vibration frequency, and detects the natural frequency using the detected potential difference.

The first sensor 4420 subtracts the magnitude of the external magnetic field in the second direction sensed by the second sensor 4440 from the magnitude of the detected external magnetic field to correct the magnitude of the external magnetic field in the first direction.

Describing the operation of the sensing apparatus, the control unit 4400 uses the first driver 4410 to drive the first magnetic field detection unit 4100 and the first reference unit 4110.

Further, the control unit 4400 uses the first sensor 4420 to detect the potential difference from the first magnetic field detection unit 4100, uses the detected potential difference to detect the vibration frequency, detects the potential difference from the first reference unit 4110 based on the detected vibration frequency, uses the detected potential difference to detect the natural frequency, and calculates the change amount of the vibration frequency using the natural frequency to detect the magnitude of the external magnetic field in the first direction.

In this case, the first sensor 4420 of the control unit 4400 calculates the magnitude of the external magnetic field which is a sum of the magnitudes of the external magnetic fields in the first direction and the second direction.

Meanwhile, the control unit 4400 uses the second driver 4430 to drive the second magnetic field detection unit 4200 and the second reference unit 4210.

Further, the control unit 4400 uses the second sensor 4440 to detect the potential difference from the second magnetic field detection unit 4200, uses the detected potential difference to detect the vibration frequency, detects the potential difference from the second reference unit 4210 based on the detected vibration frequency, uses the detected potential difference to detect the natural frequency, and calculates the change amount of the vibration frequency using the natural frequency to detect the magnitude of the external magnetic field in the second direction.

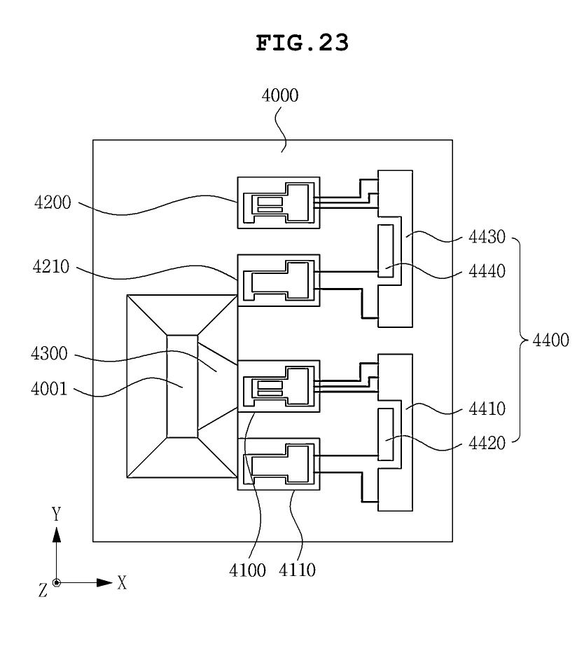

Meanwhile, the structure of FIG. 23 is the same as that of FIG. 22 except that in the structure of FIG. 22 the shape of the vibrator is changed from the cantilever structure to the bridge structure. The bridge structure is illustrated in detail in FIGS. 10 to 12. The operation of the sensing apparatus and the method for measuring a magnetic field depending on the structure of FIG. 23 are the same as the structure of FIG. 23, and therefore the operation process thereof will be omitted.

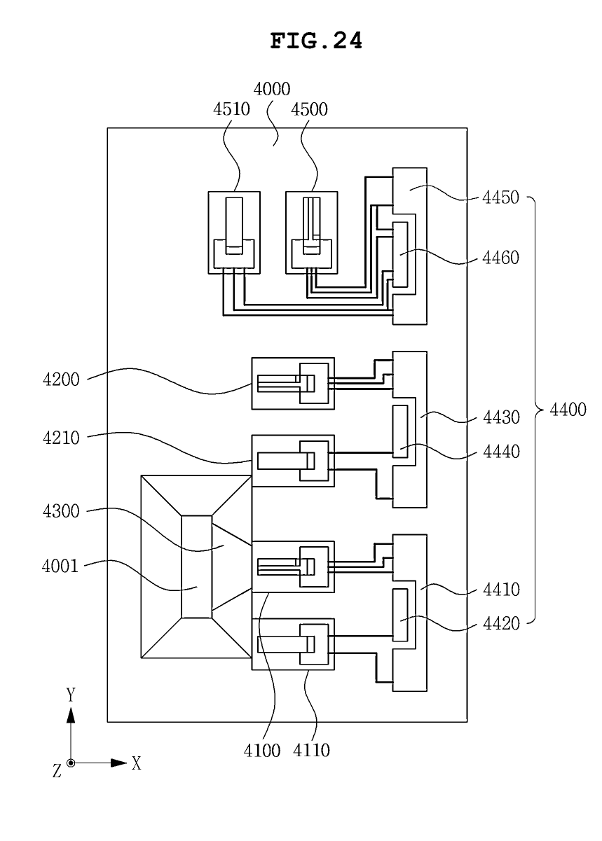

FIG. 24 is a structural view of a sensing apparatus using a magnetic field sensor according to an eleventh preferred embodiment of the present invention.

Referring to FIG. 24, a sensing apparatus using a magnetic field sensor according to an eleventh preferred embodiment of the present invention includes the first magnetic field detection unit 4100, the first reference unit 4110, the second magnetic field detection unit 4200, the second reference unit 4210, a third magnetic field detection unit 4500, a third reference unit 4510, the flux concentrator 4300, and the control unit 4400.

Comparing with the sensing apparatus according to the ninth preferred embodiment of the present invention, the sensing apparatus according to the eleventh embodiment of the present invention further includes the third magnetic field detection unit 4500 which is a right angle to the first magnetic field detection unit 4100 and the second magnetic field detection unit 4200 and further includes the third reference unit 4510 which is made of the same material and has the same structure as the third magnetic field detection unit 4500, other than the magnetostrictive layer.

Herein, the third reference unit 4510 may be a right angle to the first reference unit 4110 and the second reference unit 4210.

Further, the control unit 4400 includes a third driver 4450 which drives the third magnetic field detection unit 4500 and the third reference unit 4510 and a third sensor 4460 which uses the output voltage output from the third magnetic field detection unit 4500 and the third reference unit 4510 to calculate the magnitude of the external magnetic field in a third direction.

As such, comparing with the sensing apparatus according to the ninth preferred embodiment of the present invention, the sensing apparatus according to the eleventh embodiment of the present invention further includes the third magnetic field detection unit 4500 which is a right angle to the first magnetic field detection unit 4100 and the second magnetic field detection unit 4200 to be able to measure the magnitudes of the external magnetic fields for the first direction to the third direction (three axis directions which is a right angle to each other).

The structure of the third magnetic field detection unit 4500 as described above is the same as the magnetic field detection unit illustrated in FIGS. 4 to 6 and the detailed structure and operation thereof are described in advance and therefore the description thereof will be omitted.

Meanwhile, the structure of the third reference unit 4510 is the same as that of the reference unit illustrated in FIGS. 4 to 6 and detailed structure and operation thereof are described in advance and therefore the description thereof will be omitted.

Herein, the structure including the first to third reference units will be described, but the structure in which the reference unit is omitted is possible.

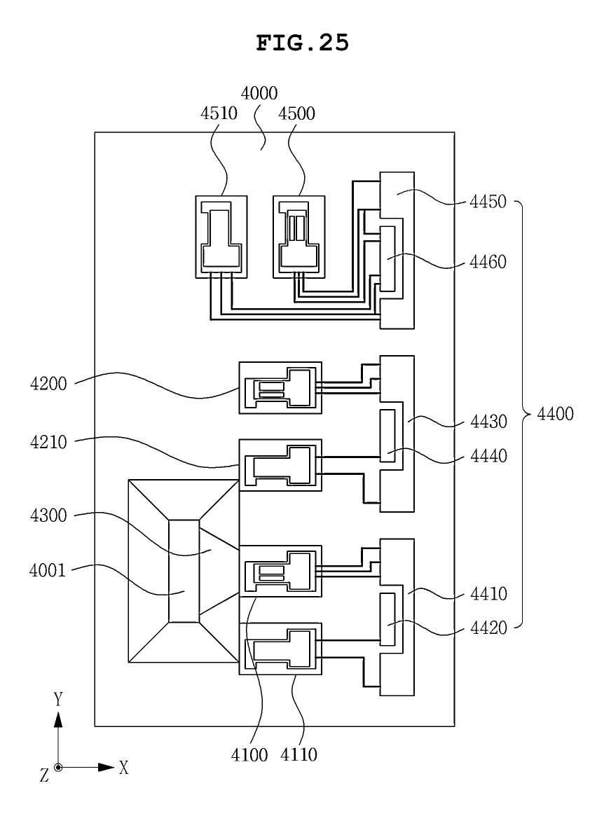

Meanwhile, the structure of FIG. 25 is the same as that of FIG. 24 except that in the structure of FIG. 22 the shape of the vibrator is changed from the cantilever structure to the bridge structure. The bridge structure is illustrated in detail in FIGS. 10 to 12. The operation of the sensing apparatus and the method for measuring a magnetic field depending on the structure of FIG. 25 are the same as the structure of FIG. 25, and therefore the operation process thereof will be omitted.

As set forth above, the sensing apparatus according to the preferred embodiments of the present invention may measure the external magnetic field of several axes without forming the electrode having the complicated shape in the piezoelectric layer.

Further, the sensing apparatus according to the preferred embodiments of the present invention may measure the external magnetic field of several axes in the low vibration frequency by preventing the overtone characteristics of the vibration due to the electrode form.

Further, according to the preferred embodiments of the present invention, it is possible to measure the magnitude of the external magnetic field vertical to a ground by using the magnetic field sensor including the magnetostrictive layer parallel with a ground by using the flux concentrator.

As the result, it is possible to solve the space restriction in implementing the multi-axis sensing apparatus.

Further, it is possible to simplify the process and save the costs since the stacking process and the etching process are performed while proceeding vertically in implementing the multi-axis sensing apparatus.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A magnetic field sensor, comprising:
a magnetic field detection unit which includes a substrate, a piezoelectric driving body formed on the substrate, and a magnetostrictive layer stacked on one portion of the piezoelectric driving body and is vibrated at a vibration frequency changed from a natural frequency in proportion to a magnitude of an external magnetic field; and
a control unit which drives the piezoelectric driving body with a constant AC voltage and calculates a magnitude of the external magnetic field from an output voltage output from the magnetic field detection unit,
wherein the piezoelectric driving body has an end fixed to the substrate and the other end protruding on a side of the substrate in the state in which the other end is not supported to the substrate and has a rectangular bar shape.

2. The magnetic field sensor as set forth in claim 1, wherein the piezoelectric driving body includes:
a first electrode which has an end fixed to the substrate and the other end protruding on a side of the substrate in the state in which the other end is not supported to the substrate and has a rectangular bar shape;
a piezoelectric layer which is stacked on the first electrode; and
a second electrode which is stacked on the piezoelectric layer.

3. The magnetic field sensor as set forth in claim 2, further comprising:
a sensing electrode which is formed to be separated from a second electrode formed on the piezoelectric layer of the piezoelectric driving body,
wherein the control unit includes a driver which applies the constant AC voltage to the first electrode and the second electrode to vibrate the piezoelectric layer; and
a sensor which measures a voltage across the piezoelectric layer using the first electrode and the sensing electrode to measure the vibration frequency based on a change amount of the voltage and calculates the change amount from the natural frequency of the measured vibration frequency to measure the magnitude of the external magnetic field.

4. The magnetic field sensor as set forth in claim 1, further comprising:
a reference unit which includes a reference piezoelectric driving body formed to have the same structure as the piezoelectric driving body of the magnetic detection unit and made of the same material as the piezoelectric driving body of the magnetic detection unit and is vibrated at the natural frequency.

5. A magnetic field sensor, comprising:
a magnetic field detection unit which includes a substrate, a piezoelectric driving body formed on the substrate, and a magnetostrictive layer stacked on one portion of the piezoelectric driving body and is vibrated at a vibration frequency changed from a natural frequency in proportion to a magnitude of an external magnetic field; and
a control unit which drives the piezoelectric driving body with a constant AC voltage and calculates a magnitude of the external magnetic field from an output voltage output from the magnetic field detection unit,
wherein the substrate is provided with a groove, and
the piezoelectric driving body includes:
a first electrode which has ends fixed to both sides of the groove and has a rectangular bar shape crossing the groove;
a piezoelectric layer which is stacked on the first electrode; and
a second electrode which is stacked on the piezoelectric layer.

6. The magnetic field sensor as set forth in claim 5, further comprising:
a sensing electrode which is formed to be separated from a second electrode formed on the piezoelectric layer of the piezoelectric driving body,
wherein the control unit includes a driver which applies the constant AC voltage to the first electrode and the second electrode to vibrate the piezoelectric layer; and
a sensor which measures a voltage across the piezoelectric layer using the first electrode and the sensing electrode to measure the vibration frequency based on a change amount of the voltage and calculates the change amount from the natural frequency of the measured vibration frequency to measure the magnitude of the external magnetic field.

7. The magnetic field sensor as set forth in claim 5, further comprising:
a reference unit which includes a reference piezoelectric driving body formed to have the same structure as the piezoelectric driving body of the magnetic detection unit and made of the same material as the piezoelectric driving body of the magnetic detection unit and is vibrated at the natural frequency.

8. A sensing apparatus, comprising:
a first magnetic field detection unit which includes a substrate, a first piezoelectric driving body formed on the substrate, and a first magnetostrictive layer stacked on one portion of the first piezoelectric driving body and is vibrated at a vibration frequency changed from a natural frequency in proportion to a magnitude of an external magnetic field in a first direction;
a second magnetic field detection unit which includes a second piezoelectric driving body formed on the substrate differently from a direction of the first piezoelectric driving body and a second magnetostrictive layer stacked on one portion of the second piezoelectric driving body and is vibrated at the vibration frequency changed from the natural frequency in proportion to a magnitude of an external magnetic field in a second direction; and
a control unit which drives the first piezoelectric driving body and the second piezoelectric driving body with a constant AC voltage and calculates the magnitudes of the external magnetic fields in the first direction and the second direction from an output voltage output from the first magnetic field detection unit and the second magnetic field detection unit,
wherein the first piezoelectric driving body has an end fixed to the substrate and the other end protruding on a side of the substrate in the state in which the other end is not supported to the substrate and has a rectangular bar shape, and
the second piezoelectric driving body has an end fixed to the substrate and the other end protruding on a side of the substrate in the state in which the other end is not supported to the substrate and has a rectangular bar shape.

9. The sensing apparatus as set forth in claim 8, wherein the first piezoelectric driving body includes:
a first electrode which has an end fixed to the substrate and the other end protruding on a side of the substrate in the state in which the other end is not supported to the substrate and has a rectangular bar shape;
a first piezoelectric layer which is stacked on the first electrode; and
a second electrode which is stacked on the first piezoelectric layer, and
wherein the second piezoelectric driving body includes:
a third electrode which has an end fixed to the substrate and the other end protruding on a side of the substrate in the state in which the other end is not supported to the substrate and has a rectangular bar shape;
a second piezoelectric layer which is stacked on the third electrode; and
a fourth electrode which is stacked on the second piezoelectric layer.

10. The sensing apparatus as set forth in claim 9, wherein the first piezoelectric driving body includes a first sensing electrode which is formed to be separated from the first electrode formed on the first piezoelectric layer, and
the second piezoelectric driving body includes a second sensing electrode which is formed to be separated from a fourth electrode formed on the second piezoelectric layer, and
the control unit includes:
a first driver which applies a constant AC voltage to the first electrode and the second electrode to vibrate the first piezoelectric layer;
a second driver which applies a constant AC voltage to the third electrode and the fourth electrode to vibrate the second piezoelectric layer;
a first sensor which measures a voltage across the first piezoelectric layer using the first electrode and the first sensing electrode to measure a first vibration frequency from a change amount of the voltage, and calculates the change amount from a first natural frequency of the measured first vibration frequency to measure the magnitude of the external magnetic field in the first direction; and
a second sensor which measures a voltage across the second piezoelectric layer using the third electrode and the second sensing electrode to measure a second vibration frequency from a change amount of the voltage, and calculates the change amount from a second natural frequency of the measured second vibration frequency to measure the magnitude of the external magnetic field.

11. The sensing apparatus as set forth in claim 8, wherein the first magnetic field detection unit includes a first reference unit which includes a first reference piezoelectric driving body formed to have the same structure as the first piezoelectric driving body and made of the same material as the first piezoelectric driving body and is vibrated at a first natural frequency; and
the second magnetic field detection unit includes a second reference unit which includes a second reference piezoelectric driving body formed to have the same structure as the second piezoelectric driving body and made of the same material as the second piezoelectric driving body and is vibrated at a second natural frequency.

12. A sensing apparatus, comprising:
a first magnetic field detection unit which includes a substrate, a first piezoelectric driving body formed on the substrate, and a first magnetostrictive layer stacked on one portion of the first piezoelectric driving body and is vibrated at a vibration frequency changed from a natural frequency in proportion to a magnitude of an external magnetic field in a first direction;
a second magnetic field detection unit which includes a second piezoelectric driving body formed on the substrate differently from a direction of the first piezoelectric driving body and a second magnetostrictive layer stacked on one portion of the second piezoelectric driving body and is vibrated at the vibration frequency changed from the natural frequency in proportion to a magnitude of an external magnetic field in a second direction; and
a control unit which drives the first piezoelectric driving body and the second piezoelectric driving body with a constant AC voltage and calculates the magnitudes of the external magnetic fields in the first direction and the second direction from an output voltage output from the first magnetic field detection unit and the second magnetic field detection unit,
wherein the substrate is provided with a groove,
the first piezoelectric driving body includes:
a first electrode which has ends fixed to both sides of the groove and has a rectangular bar shape crossing the groove;
a first piezoelectric layer which is stacked on the first electrode; and
a second electrode which is stacked on the first piezoelectric layer, and
the second piezoelectric driving body includes:
a third electrode which has ends fixed to both sides of the groove and has a rectangular bar shape crossing the groove;
a second piezoelectric layer which is stacked on the third electrode; and
a fourth electrode which is stacked on the second piezoelectric layer.

13. The sensing apparatus as set forth in claim 12, further comprising:
a first sensing electrode which is formed to be separated from the first electrode formed on the piezoelectric layer of the first piezoelectric driving body, and
a second sensing electrode which is formed to be separated from the fourth electrode formed on the piezoelectric layer of the second piezoelectric driving body,
wherein the control unit includes:
a first driver which applies a constant AC voltage to the first electrode and the second electrode to vibrate the first piezoelectric layer;
a second driver which applies a constant AC voltage to the third electrode and the fourth electrode to vibrate the second piezoelectric layer;
a first sensor which measures a voltage across the first piezoelectric layer using the first electrode and the first sensing electrode to measure a first vibration frequency from a change amount of the voltage, and calculates the change amount from a first natural frequency of the measured first vibration frequency to measure the magnitude of the external magnetic field in the first direction; and
a second sensor which measures a voltage across the second piezoelectric layer using the third electrode and the second sensing electrode to measure a second vibration frequency from a change amount of the voltage, and calculates the change amount from a second natural frequency of the measured second vibration frequency to measure the magnitude of the external magnetic field.

14. The sensing apparatus as set forth in claim 12, wherein the first magnetic field detection unit includes a first reference unit which includes a first reference piezoelectric driving body formed to have the same structure as the first piezoelectric driving body and made of the same material as the first piezoelectric driving body and is vibrated at a first natural frequency; and
the second magnetic field detection unit includes a first reference unit which includes a second reference piezoelectric driving body formed to have the same structure as the second piezoelectric driving body and made of the same material as the second piezoelectric driving body and is vibrated at a second natural frequency.

15. A sensing apparatus, comprising:
a first magnetic field detection unit which includes a substrate, a first piezoelectric driving body formed on the substrate, and a first magnetostrictive layer stacked on one portion of the first piezoelectric driving body and is vibrated at a first vibration frequency changed from a first natural frequency in proportion to a magnitude of an external magnetic field in a first direction vertical to the first magnetostrictive layer;
a flux concentrator which is mounted in parallel with the external magnetic field in the first direction to induce the external magnetic field in the first direction to a first magnetostrictive layer of the first magnetic field detection unit; and
a control unit which drives the first piezoelectric driving body with a constant AC voltage and calculates a magnitude of the external magnetic field in the first direction from an output voltage output from the first magnetic field detection unit.

16. The sensing apparatus as set forth in claim 15, wherein the first piezoelectric driving body has an end fixed to the substrate and the other end protruding on a side of the substrate in the state in which the other end is not supported to the substrate and has a rectangular bar shape.

17. The sensing apparatus as set forth in claim 16, wherein the first piezoelectric driving body includes:
a first electrode which has an end fixed to the substrate and the other end protruding on a side of the substrate in the state in which the other end is not supported to the substrate and has a rectangular bar shape;
a first piezoelectric layer which is stacked on the first electrode; and
a second electrode which is stacked on the first piezoelectric layer.

18. The sensing apparatus as set forth in claim 17, further comprising:
a first sensing electrode which is formed to be separated from the second electrode formed on the first piezoelectric layer of the first piezoelectric driving body,
wherein the control unit includes a first driver which applies a constant AC voltage to the first electrode and the second electrode to vibrate the first piezoelectric layer; and
a first sensor which measures a voltage across the first piezoelectric layer using the first electrode and the first sensing electrode to measure a vibration frequency from a change amount of the voltage and calculates the change amount from the natural frequency of the measured vibration frequency to measure the magnitude of the external magnetic field.

19. The sensing apparatus as set forth in claim 15, further comprising:
a first reference magnetic field detection unit which includes a first reference piezoelectric driving body formed to have the same structure as the first piezoelectric driving body of the first magnetic field detection unit and made of the same material as the first piezoelectric driving body of the first magnetic field detection unit and is vibrated at the first natural frequency.

20. The sensing apparatus as set forth in claim 15, wherein the substrate is provided with a first groove, and
the first piezoelectric driving body includes:
a first electrode which has ends fixed to both sides of the first groove and has a rectangular bar shape crossing the first groove;
a first piezoelectric layer which is stacked on the first electrode; and
a second electrode which is stacked on the piezoelectric layer.

21. The sensing apparatus as set forth in claim 20, further comprising:
a first reference magnetic field detection unit which includes a first reference piezoelectric driving body formed to have the same structure as the first piezoelectric driving body of the first magnetic field detection unit and made of the same material as the first piezoelectric driving body of the first magnetic field detection unit and is vibrated at the first natural frequency.

22. The sensing apparatus as set forth in claim 15, further comprising:
a second magnetic field detection unit which includes a second piezoelectric driving body formed on the substrate in the same direction as the first piezoelectric driving body and a second magnetostrictive layer stacked on one portion of the second piezoelectric driving body and is vibrated at a second vibration frequency changed from a second natural frequency in proportion to the magnitude of the external magnetic field in the second direction in parallel with the first and second magnetostrictive layers,
wherein the control unit drives the first piezoelectric driving body and the second piezoelectric driving body with the constant AC voltage, calculates the magnitude of the external magnetic field in the second direction from the output voltage output from the second magnetic field detection unit to correct the magnitude of the external magnetic field in the first direction calculated from the output voltage output from the first magnetic field detection unit using the magnitude of the external magnetic field in the second direction.

23. The sensing apparatus as set forth in claim 22, wherein the substrate is provided with a first groove,
the first piezoelectric driving body includes:
a first electrode which has one end fixed to the substrate and the other end levitated in the state in which the other end is not supported to the substrate and has a bar shape;
a first piezoelectric layer which is stacked on the first electrode; and
a second electrode which is stacked on the piezoelectric layer, and
the second piezoelectric driving body includes:
a third electrode which has one end fixed to the substrate and the other end levitated in the state in which the other end is not supported to the substrate and has a bar shape;
a second piezoelectric layer which is stacked on the third electrode; and
a fourth electrode which is stacked on the second piezoelectric layer.

24. The sensing apparatus as set forth in claim 23, further comprising:
a first reference unit which includes a first reference piezoelectric driving body formed to have the same structure as the first piezoelectric driving body of the first magnetic field detection unit and made of the same material as the first piezoelectric driving body of the first magnetic field detection unit and is vibrated at a first natural frequency; and
a second reference unit which includes a second reference piezoelectric driving body formed to have the same structure as the second piezoelectric driving body of the second magnetic field detection unit and made of the same material as the second piezoelectric driving body of the second magnetic field detection unit and is vibrated at a second natural frequency.

25. The sensing apparatus as set forth in claim 22, wherein the substrate is provided with a first groove,
the first piezoelectric driving body includes:
a first electrode which has ends fixed to both sides of the first groove and has a rectangular bar shape crossing the first groove;
a first piezoelectric layer which is stacked on the first electrode; and
a second electrode which is stacked on the piezoelectric layer, and
the second piezoelectric driving body includes:
a third electrode which has ends fixed to both sides of the first groove and has a rectangular bar shape crossing the first groove;
a second piezoelectric layer which is stacked on the third electrode; and
a fourth electrode which is stacked on the second piezoelectric layer.

26. The sensing apparatus as set forth in claim 25, further comprising:
a first reference unit which includes first reference piezoelectric driving body formed to have the same structure as the first piezoelectric driving body of the first magnetic field detection unit and made of the same material as the first piezoelectric driving body of the first magnetic field detection unit and is vibrated at a first natural frequency; and
a second reference unit which includes a second piezoelectric driving body formed to have the same structure as the second piezoelectric driving body of the second magnetic field detection unit and made of the same material as the second piezoelectric driving body of the second magnetic field detection unit and is vibrated at a second natural frequency.

27. The sensing apparatus as set forth in claim 15, wherein the flux concentrator is formed on a side of the substrate.

28. The sensing apparatus as set forth in claim 27, wherein the flux concentrator has a rectangular shape.

29. The sensing apparatus as set forth in claim 15, wherein the flux concentrator has a trapezoidal shape in which a width adjacent to the second piezoelectric driving body is smaller than that of the opposite side thereof.

30. The sensing apparatus as set forth in claim 15, wherein the substrate is provided with a second groove, and
the flux concentrator is formed on a side of the second groove.

31. The sensing apparatus as set forth in claim 22, further comprising:
a third magnetic field detection unit which includes a third piezoelectric driving body having a different direction from the first piezoelectric driving body formed on the substrate and a third magnetostrictive layer stacked on one portion of the third piezoelectric driving body and is vibrated at a third vibration frequency changed from a third natural frequency in proportion to a magnitude of an external magnetic field in a third direction,
wherein a control unit drives the third piezoelectric driving body with a constant AC voltage and calculates the magnitude of the external magnetic field in the third direction from an output voltage output from the third magnetic field detection unit.
